(19) United States
(12) Patent Application Publication
(10) Pub. No.: US 2010/0077276 A1
(43) Pub. Date: Mar. 25, 2010

(54) TRANSMITTING DEVICE, RECEIVING DEVICE, ENCODER, AND ENCODING METHOD

(75) Inventors: Shutai Okamura, Osaka (JP); Yutaka Murakami, Osaka (JP); Masayuki Orihashi, Kanagawa (JP); Takaaki Kishigami, Tokyo (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, Osaka (JP)

(21) Appl. No.: 12/527,171

(22) PCT Filed: Feb. 15, 2008
(86) PCT No.: PCT/JP2008/000239

§ 371 Date: Aug. 13, 2009

(30) Foreign Application Priority Data
Feb. 16, 2007 (JP) 2007-036941
Feb. 14, 2008 (JP) 2008-033241

(51) Int. Cl. H03M 13/05; G06F 11/10

(52) U.S. Cl. 714/752; 714/E11.032

(57) ABSTRACT

In such a relationship between information transmitted by a primary BCH, for example, and information transmitted by a non-primary BCH as a case of the transmission for a first information sequence that is easy to keep receiving quality and a second information sequence that is difficult to keep receiving quality, a transmitting device and a receiving device are disclosed for making it possible to improve an error rate of the second information sequence. In the devices, an encoder (102) encodes a non-primary BCH information sequence (Sn) with a long code length including a primary BCH information sequence (Sp). On the receiving side, a non-primary BCH information sequence is decoded with a long code length by using the received primary BCH value. With this, a higher encoding gain than encoding only with the non-primary BCH information can be obtained, so that a receiving characteristic of the non-primary BCH can be improved.

### TECHNICAL FIELD

The present invention relates to a transmitting apparatus, receiving apparatus, encoder and encoding method for performing forward error correction (FEC) processing.

### BACKGROUND ART

Recently, in 3GPP (3rd Generation Partnership Project), wireless access networks based on IP (Internet Protocol) such as Evolved UTRA (UMTS Terrestrial Radio Access) and UTRAN (UMTS Terrestrial Radio Access Network) are standardized as improvements of the third generation cellular mobile communication system. With Evolved UTRA, when the 20 MHz band is used, the target maximum rate is specified at 100 Mbps in downlink and 50 Mbps in uplink. Consequently, the frequency utilization efficiency at the maximum rate is 5 bps/Hz in downlink and 2.5 Mbps/Hz in uplink.

Non-Patent Document 1 proposes a configuration of a broadcast channel (BCH) in downlink in Evolved UTRA. FIG. 1 shows the proposed configuration of a BCH. With this configuration, a BCH is layered into two kinds of a primary BCH and a non-primary BCH to transmit. In the primary BCH, information that needs to be received first after cell search, such as the bandwidth used by the base station, is transmitted. Therefore, the primary BCH is fixedly assigned to the resources determined in advance by the system and is transmitted. Further, in the primary BCH, the same information is transmitted to all sectors of one base station, at the same time.

By contrast with this, in the non-primary BCH, dedicated information for each sector or each mobile terminal is transmitted. Here, the non-primary BCH is received after the primary BCH is received, so that the non-primary BCH can be assigned to resources other than the resources determined in advance and transmitted. Furthermore, dedicated information for each sector and each mobile terminal is transmitted through the non-primary BCH, so that, in the non-primary BCH, signals that vary between base stations, sector antennas, and/or frames are transmitted.

For example, as shown in FIG. 1, when a mobile terminal has reception performance with the 10 MHz bandwidth, the primary BCH is transmitted at around the 1.25 bandwidth and the non-primary BCH is transmitted at around the 5 MHz bandwidth. Further, shared data channels in which data for a plurality of mobile terminals are multiplexed, are assigned to the other bands.

Here, it is desirable in Evolved UTRA to improve received quality of the primary BCH to make coverage of a cell wider. However, the primary BCH is transmitted at a small frequency bandwidth of 1.25 MHz and, therefore, it is difficult to increase gain by carrying out frequency diversity.

As shown in FIG. 2, Non-Patent Document 1 aims at improving received quality by transmitting information to a plurality of sectors through primary BCH's at the same time and soft-combining and receiving information in a mobile terminal, and shows its effectiveness. Further, the primary BCH signals are transmitted at the head of every radio frame and are common between all frames, so that it is possible to increase gain by carrying out time diversity.

Non-Patent Document 1: “Investigations on Broadcast Channel Structure in Evolved UTRA Downlink” Higuchi et al., Institute of Electronics, Information and Communication Engineers Society Convention proceeding B-5-30, 2006

### DISCLOSURE OF INVENTION

### Problems to be Solved by the Invention

As described above, it is easy to improve received quality (i.e. the error rate characteristics) of information transmitted in primary BCH's by means of combination and a diversity technique.

However, signals that vary between sectors and frames are transmitted in non-primary BCH's and, therefore, there is a problem that, when non-primary BCH's are received, non-primary BCH's in other sectors interfere. Therefore, the technique of improving the received quality (i.e. the error rate characteristics) of information transmitted in non-primary BCH's is required.

It is therefore an object of the present invention to provide a transmitting apparatus and receiving apparatus that can improve the error rate characteristics of the second information sequence that hardly secures received quality when the first information sequence that secures received quality at ease and the second information sequence that hardly secures received quality are transmitted like, for example, the relationship between information transmitted in primary BCH's and information transmitted in non-primary BCH's.

Furthermore, it is another object of the present invention to provide a transmitting apparatus, receiving apparatus, encoder and encoding method for improving the error rate characteristics of the second information sequence when the receiving apparatus is configured to receive the first information sequence correctly and then receive the second information sequence like the relationship between information transmitted in primary BCH's and information transmitted in non-primary BCH's.

### Means for Solving the Problem

An aspect of the transmitting apparatus according to the present invention that transmits a first information sequence and a second information sequence, employs a configuration which includes a first encoder that encodes the first information sequence; a second encoder that encodes a sequence jointing the first information sequence and the second information sequence; and a transmitting section that transmits encoded sequences acquired in the first and second encoders.

According to this configuration, the second encoder encodes a sequence jointing the first information sequence and the second information sequence, and, consequently, the code length of the second information sequence can be increased and the increase in coding gain equaling the increase in the code length can be produced when the second information sequence is decoded, so that it is possible to improve the error rate characteristics of the second information sequence that hardly secures received quality.

Further, one aspect of the transmitting apparatus according to the present invention employs a configuration in which the transmitting section transmits: the encoded sequence of the first information sequence acquired in the first encoder, and the encoded sequence of the second information sequence and a parity sequence, except for the encoded sequence of the first information sequence from the encoded sequence of the first information sequence, the encoded sequence of the second information sequence and the parity sequence acquired in the second encoder.

According to this configuration, it is possible to transmit a minimum amount of data such that the receiving side can decode the first and second encoded sequences.

Further, one aspect of the receiving apparatus according to the present invention employs a configuration which includes: a first decoder that decodes a first encoded sequence to acquire a first information sequence; and a second decoder that decodes data jointing the first information sequence acquired in the first decoder and a second encoded sequence to acquire a second information sequence.

According to this configuration, it is possible to decode the first and second information sequences before encoding, from the first and second encoded sequences transmitted from the transmitting apparatus according to the present invention.

Further, one aspect of the encoder according to the present invention that encodes a first information sequence and a second information sequence, employs a configuration which generates a first parity sequence from the first information sequence and a second parity sequence from the first information sequence and the second information sequence.

According to this configuration, the second encoder encodes a sequence jointing the first information sequence and the second information sequence and, consequently, the code length of the second information sequence can be increased and the increase in coding gain equaling the increase in the code length can be produced when the second information sequence is decoded, so that it is possible to improve the error rate characteristics of the second information sequence that hardly secures received quality.

### ADVANTAGEOUS EFFECTS OF INVENTION

The present invention can provide a transmitting apparatus and receiving apparatus that can improve the error rate characteristics of the second information sequence that hardly secures received quality when the first information sequence that secures received quality at ease and the second information sequence that hardly secures received quality are transmitted. Furthermore, the present invention can provide a transmitting apparatus, receiving apparatus, encoder and encoding method for improving the error rate characteristics of the second information sequence when the receiving apparatus is configured to receive the first information sequence correctly and then receive the second information sequence.

### BRIEF DESCRIPTION OF DRAWINGS

FIG. 1 shows a configuration example of a broadcast channel (BCH);

FIG. 2 shows an image of Soft-Decision Decoding in a mobile terminal in primary BCH's;

FIG. 3 is a block diagram showing the configuration of a transmitting apparatus according to Embodiment 1 of the present invention;

FIG. 4 illustrates the configuration of an encoder according to Embodiment 1;

FIG. 5 illustrates another configuration of the encoder according to Embodiment 1;

FIG. 6 is a block diagram showing the configuration of a receiving apparatus according to Embodiment 1;

FIG. 7 is a block diagram showing the configuration of a decoder according to Embodiment 1;

FIG. 8 illustrates the operation of an LDPC decoder according to Embodiment 1;

FIG. 9 shows an image of a layered transmission scheme in terrestrial digital data broadcasting;

FIG. 10 is a block diagram showing the configuration of the transmitting apparatus according to Embodiment 2;

FIG. 11 illustrates the configuration of an inner encoder according to Embodiment 2;

FIG. 12 illustrates another configuration of the inner encoder according to Embodiment 2;

FIG. 13 is a block diagram showing the configuration of the transmitting apparatus according to Embodiment 3;

FIG. 14 illustrates the configuration of an error correction/detection encoder according to Embodiment 3;

FIG. 15 is a block diagram showing the configuration of the receiving apparatus according to Embodiment 3;

FIG. 16 is a block diagram showing the configuration of an error correction decoder according to Embodiment 3;

FIG. 17 illustrates the operation according to Embodiment 3;

FIG. 18 shows the relationship between input and output of an encoder according to Embodiment 4 of the present invention;

FIG. 19 shows a configuration example of a parity check matrix H according to Embodiment 4;

FIG. 20 shows the configuration of the check matrices T1 and T2;

FIG. 21 shows the configuration of the encoder according to Embodiment 4;

FIG. 22 shows another configuration of the parity check matrix H according to Embodiment 4;

FIG. 23 shows another configuration of the check matrices T1 and T2;

FIG. 24 shows the relationship between input and output of the encoder according to Embodiment 4;

FIG. 25 shows the configuration and relationship between input and output of the decoder according to Embodiment 4;

FIG. 26 shows another configuration of the decoder according to Embodiment 4;

FIG. 27 shows another configuration of the decoder according to Embodiment 4;

FIG. 28 shows another configuration of the parity check matrix H according to Embodiment 4;

FIG. 29 shows the configuration of the encoder according to Embodiment 5 of the present invention;

FIG. 30 shows another configuration of the encoder according to Embodiment 5;

FIG. 31 shows the configuration of the encoder according to Embodiment 6 of the present invention;

FIG. 32 shows the configuration of the parity check matrix H according to Embodiment 6;

FIG. 33 shows the configuration of the decoder according to Embodiment 6;

FIG. 34 shows the configuration of the encoder according to Embodiment 7 of the present invention;

FIG. 35 shows the configuration of the decoder according to Embodiment 7;

FIG. 36 shows an overall configuration of a communication system according to Embodiment 8 of the present invention;

FIG. 37 shows the configuration of an erasure correction encoder according to Embodiment 8;

FIG. 38 shows the configuration of the parity check matrix H according to Embodiment 8;

FIG. 39 shows another configuration of the erasure correction encoder according to Embodiment 8;

FIG. 40 shows a flowchart of transmitting and receiving signals in the communication system according to Embodiment 8;

FIG. 41 shows an overall configuration of the communication system according to Embodiment 9 of the present invention;

FIG. 42 shows packet sequences generated by a packet generating section according to Embodiment 9;

FIG. 43 is a block diagram showing the configuration of main parts of the erasure correction encoder according to Embodiment 9;

FIG. 44 is a block diagram showing the configuration of main parts of the erasure correction encoder according to Embodiment 9;

FIG. 45 illustrates the operation of the erasure correction encoder according to Embodiment 9;

FIG. 46 is a Tanner graph used in the erasure correction encoder according to Embodiment 9;

FIG. 47 shows an example of interleaving patterns according to Embodiment 9; and

FIG. 48 illustrates the operation of the erasure correction decoder according to Embodiment 9.

### BEST MODE FOR CARRYING OUT THE INVENTION

Hereinafter, embodiments of the present invention will be explained in details below with reference to the accompanying drawings.

### Embodiment 1

With the present embodiment, a base station and a mobile terminal that improve received quality of non-primary BCH's in Evolved UTRA, will be explained.

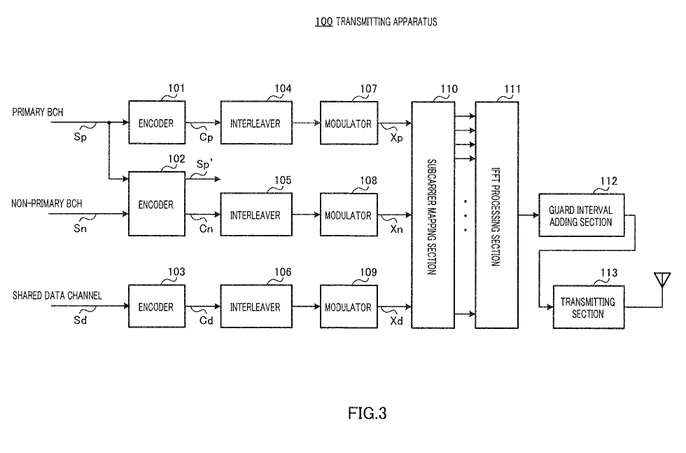

FIG. 3 shows the configuration of a transmitting apparatus according to Embodiment 1 of the present invention. Transmitting apparatus 100 is provided in the base station. Transmitting apparatus 100 transmits an information sequence Sp in the primary BCH, an information sequence Sn in the non-primary BCH and an information sequence Sd in the shared data channel (SDCH). The primary BCH information sequence Sp includes base-station specific information such as information about the bandwidth that is used and so on. The non-primary BCH information sequence Sn includes sector and mobile-terminal specific information. The SDCH information sequence Sd includes transmission data for a plurality of mobile terminals.

Encoder 101 performs error correction coding processing of the primary BCH information sequence Sp, at a predetermined code length and coding rate, and outputs an encoded sequence Cp. Here, for the coding scheme, low-density parity-check (LDPC) coding and turbo coding which involve a block code may be used. Interleaver 104 performs interleaving processing of the encoded sequence Cp. Modulator 107 performs digital modulation such as PSK (Phase Shift Keying) or QAM (Quadrature Amplitude Modulation) of the interleaved encoded sequence Cp, and outputs the modulated symbol Xp.

Encoder 102 performs error correction coding processing of sequence Sc (=[Sp Sn]) jointing the primary BCH information sequence Sp and the non-primary BCH information sequence Sn, at a predetermined code length and coding rate. By so doing, it is possible to increase the code length compared to cases where error correction coding processing is performed using the information sequence Sn alone. Assuming that the resulting parity sequence is Pc, encoder 102 outputs an encoded sequence Cn (=[Sn Pc]) to interleaver 105, and discards an encoded sequence Sp′ for the information sequence Sp. Interleaver 105 performs interleaving processing of the encoded sequence Cn. Modulator 108 performs digital modulation such QPSK or QAM of the interleaved encoded sequence Cn, and outputs a modulated symbol Xn.

Encoder 103 performs error correction coding processing of the information sequence Sd on the SDCH, at a predetermined code length and coding rate, and outputs an encoded sequence Cd. Interleaver 106 performs interleaving processing of the encoded sequence Cd. Modulator 109 performs digital modulation such as QPSK or QAM of the interleaved encoded sequence Cd, and outputs a modulated symbol Xd.

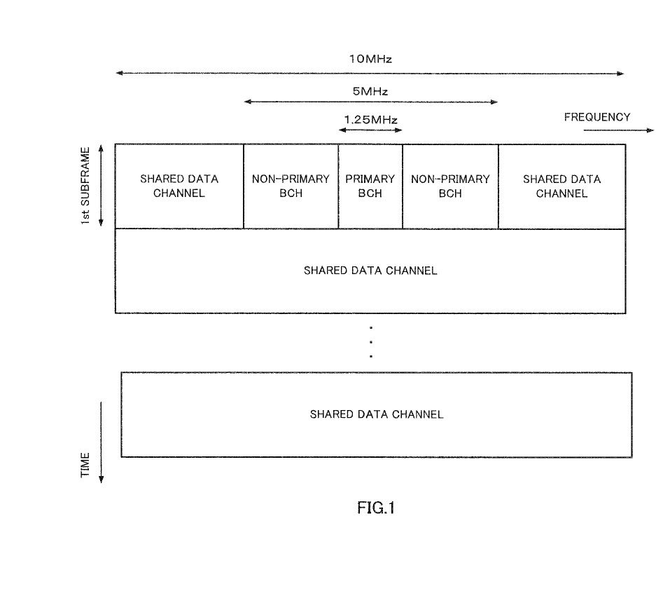

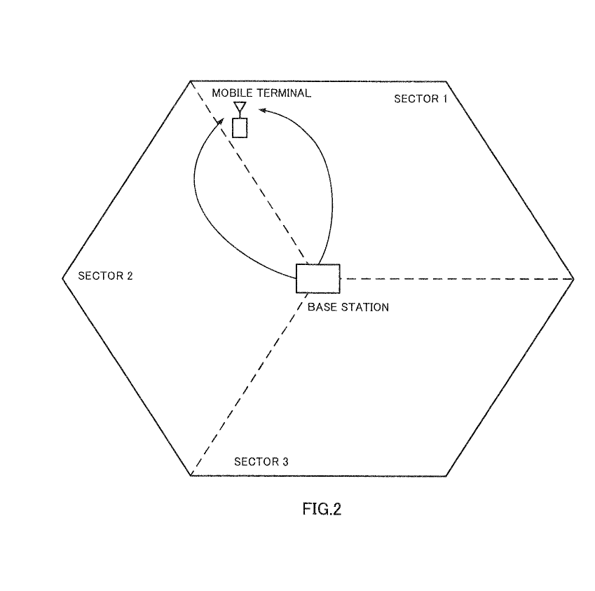

Subcarrier mapping section 110 maps the modulated symbols Xp, Xn and Xd on the subcarriers of an OFDM (Orthogonal Frequency Division Multiplexing) signal. The configuration shown in FIG. 1 may be employed as an example of the mapping method. In this case, Xp is mapped in the center 1.25 MHz band, Xn is mapped in the 5 MHz band excluding the center 1.25 MHz band, and Xd is mapped in the rest of bands. Further, the primary BCH and non-primary BCH are transmitted only at a head subframe of a transmission frame and, when other subframes are transmitted, subcarrier mapping section 110 maps Xd on all subcarriers.

IFFT processing section 111 performs an IFFT of subcarrier signals to perform multicarrier modulation. Guard interval adding section 112 adds a guard interval of a predetermined length to the head of a modulated multicarrier signal. Transmitting section 113 performs signal transmitting processing such as D/A conversion, frequency conversion and amplification of the modulated multicarrier signal with a guard interval, and supplies the signal after these processings to the transmission antenna.

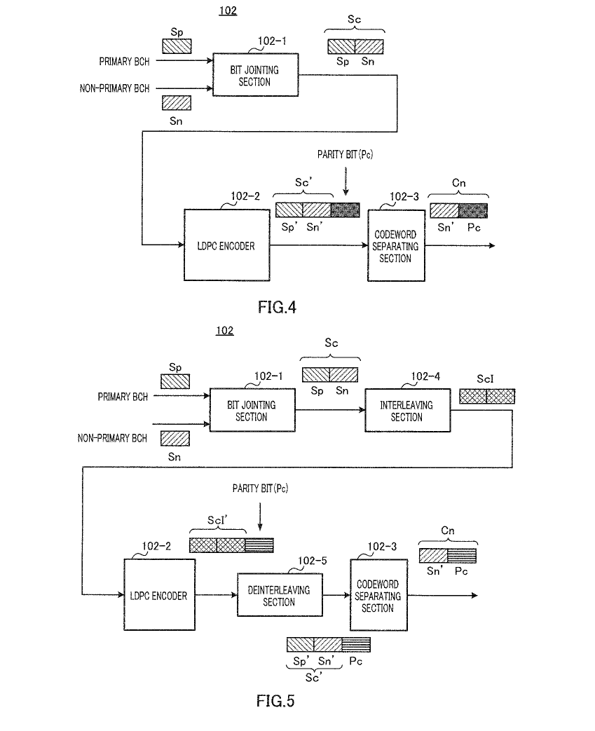

FIG. 4 shows the configuration of encoder 102. Encoder 102 in FIG. 4 has bit jointing section 102-1, LDPC encoder 102-2 and codeword separating section 102-3. Encoder 102 inputs the primary BCH information sequence Sp and the non-primary BCH information sequence Sn to bit jointing section 102-1, and outputs a sequence Sc (=[Sp Sn]) jointing these sequences. LDPC encoder 102-2 performs LDPC-coding of the jointed sequence Sc to output an encoded sequence Sc′ of the jointed sequence Sc and parity sequence Pc (i.e. parity bits). Codeword separating section 102-3 separates an encoded sequence Sn′ of the non-primary BCH information sequence Sn out of the encoded sequence Sc′ and parity sequence Pc (i.e. parity bits) from input data, and outputs only the encoded sequence Sn′ and parity sequence Pc.

That is, out of the primary BCH encoded sequence Sp′, the non-primary BCH encoded sequence Sn′ and parity sequence Pc acquired in LDPC encoder 102-2, codeword separating section 102-3 does not output the non-primary BCH encoded sequence Sp′, and outputs the non-primary BCH encoded sequence Sn′ and parity sequence Pc as the encoded sequence Cn.

In this way, encoder 102 does not encode a non-primary BCH information sequence Sn alone and encodes an information sequence Sc jointing the primary BCH information sequence Sp and the non-primary BCH information sequence Sn to acquire an encoded sequence Cn formed with the non-primary BCH encoded sequence Sn′ and parity sequence Pc, so that it is possible to increase the code length of the non-primary BCH compared to the case where the information sequence Sn alone is subjected to error correction coding processing. As a result, it is possible to improve the error rate characteristics with respect to the non-primary BCH information sequences Sn.

FIG. 5 shows another configuration example of encoder 102. Compared to the configuration of FIG. 4, in encoder 102 in FIG. 5, interleaving section 102-4 is provided between bit jointing section 102-1 and LDPC encoder 102-2, and deinterleaving section 102-5 is provided between LDPC encoder 102-2 and codeword separating section 102-3. That is, LDPC encoder 102-2 performs LDPC-coding of the interleaved jointed sequence ScI.

Deinterleaving section 102-5 performs deinterleaving processing of only the encoded sequence Sc I′ out of the encoded sequence ScI′ and parity bit Pc, and outputs the encoded sequence Sc′ and parity bit Pc. In this way, with the configuration in FIG. 5, the interleaved jointed sequence ScI is subjected to LDPC coding, so that it is possible to prevent deterioration in error correction performance caused by the arrangement of data of the non-primary BCH information sequence Sn and improve the error rate characteristics with respect to the non-primary BCH information sequence Sn.

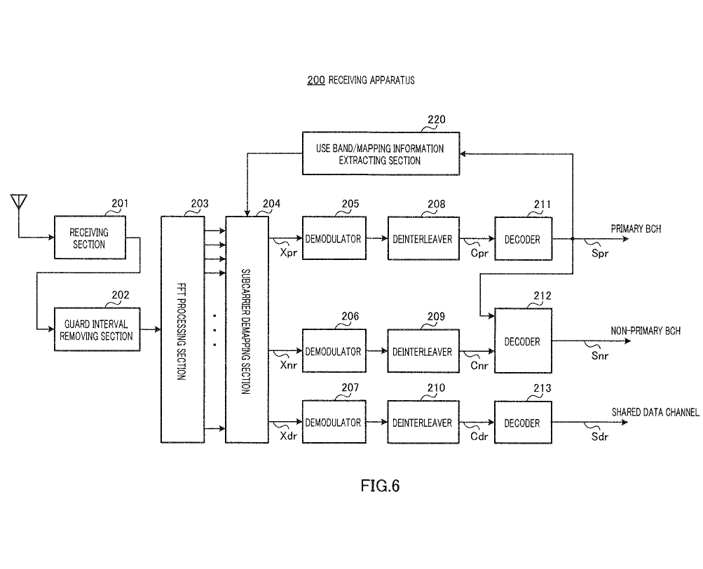

FIG. 6 shows the configuration of a receiving apparatus according to Embodiment 1 of the present invention. Receiving apparatus 200 is provided in a mobile terminal. Receiving apparatus 200 receives signals transmitted from transmission apparatus 100 (i.e. base station), through the receiving antenna. Receiving section 201 performs received signal processing such as frequency conversion, amplification, A/D conversion and frequency/time synchronization of received signals. Guard interval removing section 202 removes the guard interval added to the head of each received OFDM symbol. FFT processing section 203 performs an FFT of signals from which guard intervals are removed, to extract subcarrier signals.

Subcarrier demapping section 204 extracts a primary BCH received symbol Xpr which is mapped on a predetermined subcarrier, and outputs the received symbol Xpr to demodulator 205. Demodulator 205 demodulates and outputs the received symbol Xpr to deinterleaver 208. Deinterleaver 208 outputs a primary BCH encoded sequence Cpr. Decoder 211 decodes the encoded sequence Cpr, which is encoded at a predetermined code length and coding rate, to acquire a primary BCH information sequence Spr.

In receiving apparatus 200 (i.e. mobile terminal), use band/mapping information extracting section 220 extracts items of information, which are included in the primary BCH information sequence Spr, about the frequency bandwidth that is used in transmitting apparatus 100 (i.e. base station), and the frequency band in which the non-primary BCH is mapped, and outputs these items of information to subcarrier demapping section 204. Subcarrier demapping section 204 extracts a non-primary BCH symbol Xnr and an SDCH symbol Xdr assigned to predetermined subcarriers, based on use band/mapping information, and outputs these symbols Xnr and Xdr to demodulators 206 and 207, respectively.

Here, if there is an error in the primary BCH information sequence Spr decoded in decoder 211, receiving apparatus 200 cannot read use band/mapping information and, therefore, stops receiving processing until the primary BCH information sequence of the next transmission frame is received.

Demodulator 206 demodulates and outputs the non-primary BCH received symbol Xnr to deinterleaver 209. Deinterleaver 209 outputs the non-primary BCH encoded sequence Cnr.

Decoder 212 acquires the non-primary BCH information sequence Snr using the non-primary BCH encoded sequence Cnr and the primary BCH decoded information sequence Spr. Practically, decoder 212 acquires the non-primary BCH information sequence Snr by jointing the non-primary BCH encoded sequence Cnr and the primary BCH information sequence Spr and decoding this jointed sequence Cc (=[Spr Cnr]).

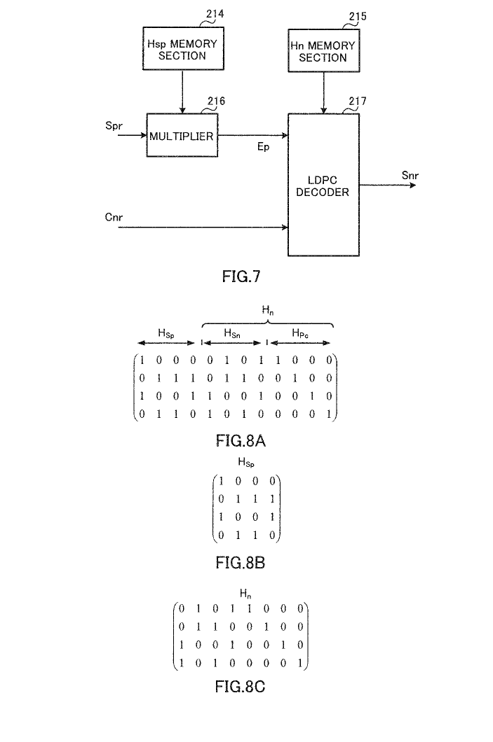

FIG. 7 shows the configuration of decoder 212. The configuration in FIG. 7 is an example of a case where the transmission side adopts LDPC coding as a coding scheme and LDPC code is adopted for the error correction coding scheme. Decoder 212 is constituted by Hsp memory section 214, Hn memory section 215, multiplier 216 and LDPC decoder 217.

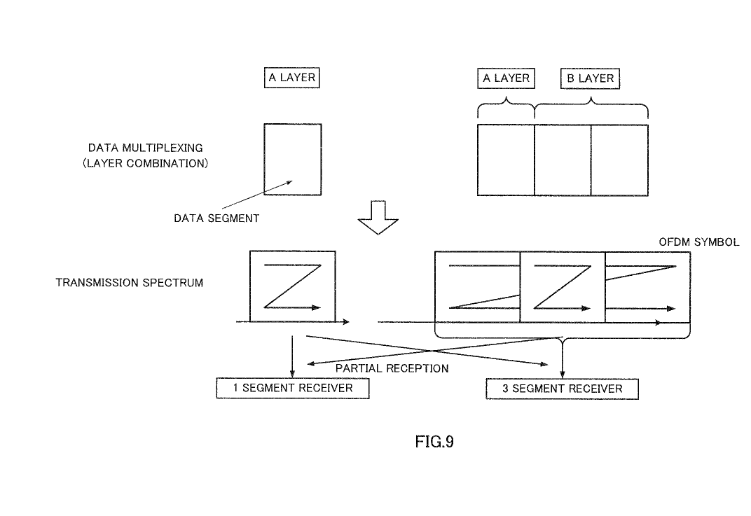

The operation of decoder 212 will be explained below with reference to an example. A case will be discussed where a parity check matrix shown in FIG. 8A is used. This parity check matrix defines an LDPC code where the code length is 12 and the coding rate is 2/3. In the parity check matrix, submatrices corresponding to Sp, Sn and Pc are defined as lisp (FIG. 8B), Hsn and Hpc, respectively. Further, assume that Hn=[Hsn Hpc] (FIG. 8C) holds. Hsp memory section 214 stores the submatrix Hsp. Further, Hn memory section 215 stores the submatrix Hn.

Multiplier 216 performs matrix multiplication of the primary BCH information sequence Spr decoded in decoder 211 and the submatrix Hsp stored in Hsp memory section 214. Here, assuming that Spr is (s1, s2, s3, s4), the multiplication result Ep=(e1, e2, e3, e4) is represented by following equation 1.

$$\begin{matrix}( Equation 1 ) & \\ \begin{matrix}Ep = Hsp \times Spr \\ = ( \begin{matrix}e 1 \\ e 2 \\ e 3 \\ e 4\end{matrix} ) \\ = ( \begin{matrix}1 & 0 & 0 & 0 \\ 0 & 1 & 1 & 1 \\ 1 & 0 & 0 & 1 \\ 0 & 1 & 1 & 0\end{matrix} ) ( \begin{matrix}s 1 \\ s 2 \\ s 3 \\ s 4\end{matrix} )\end{matrix} & [ 1 ]\end{matrix}$$

Further, multiplier 216 converts each element of Ep represented by “0” or “1,” into a symbol represented by “1” or “−1.” Then, multiplier 216 outputs the multiplication result Ep to LDPC decoder 217. LDPC decoder 217 performs LDPC decoding processing using the multiplication result Ep in multiplying section 216, the encoded sequence Cnr transmitted from deinterleaver 209 and the submatrix Hn stored in Hn memory section 215.

The LDPC decoding algorithm executed in LDPC decoder 217 will be described below. LDPC decoder 217 performs LDPC decoding based on min-sum decoding. Here, the submatrix Hn is a two-dimensional (K×J) matrix and is an LDPC code parity check matrix. With the example of FIG. 8, K is four and J is eight. Here, the element in the k-th row and the j-th column of the parity check matrix Hn is represented as “element Hₖⱼ.” Subsets A(k) and B(j) of a set [1,J] is defined as in following equation (2).

[2]

A(k)≡{j:Hₖⱼ=1}

B(j)≡{k:Hₖⱼ=1} (Equation 2)

That is, A(k) represents the set of column indices having “1” as the elements in the k-th row of the parity check matrix H, and B(j) represents the set of row indices having “1” as the elements in the j-th column of the parity check matrix H. The rest of elements j′ excluding the element j from the set A(k) are represented as “j′εA(k)\j.” Similarly, the rest of elements k′ excluding the element k from the set B(j) are represented as “k′εB(j)\k.”

Step 1 (initialization): the logarithmic a prior ratio βₖⱼ=0 holds for all sets (k, j) satisfying Hₖⱼ=1. Further, the variable that serves to count the number of repetitions is q=1 and the maximum number of repetitions is set to Q.

Step 2 (row processing): the logarithmic extrinsic ratio αₖⱼ is updated for all sets (k, j) meeting Hₖⱼ=1 in order from k=1, k=2, . . . , and k=K, utilizing the following update equation 3.

$$\begin{matrix}( Equation 3 ) & \\ {α}_{kj} = ( {\prod }_{{j}^{′} ∈ A ( k ) \backslash j} sign ( {λ}_{{j}^{′}} + {β}_{{kj}^{′}} ) ) {min}_{{j}^{′} ∈ A ( k ) \backslash j} \vert {λ}_{{j}^{′}} + {β}_{{kj}^{′}} \vert \cdot sign ( {e}_{k} ) & [ 3 ]\end{matrix}$$

Further, λⱼ in equation 3 corresponds to the non-primary BCH encoded sequence Cn, and (ĉ₁ to ĉ_{J}) corresponds to the non-primary BCH encoded sequence Cnr.

Step 3 (column processing): βₖⱼ is updated for all sets (k, j) meeting Hₖⱼ=1 in order from j=1, j=2, . . . , and j=J, utilizing following updating equation 4.

$$\begin{matrix}( Equation 4 ) & \\ {β}_{kj} = {\sum }_{{k}^{′} ∈ B ( j ) / k} {α}_{{k}^{′} j} & [ 4 ]\end{matrix}$$

Step 4 (calculation of the posterior probability): the LLR after min-sum decoding is given as following equation 5.

$$\begin{matrix}( Equation 5 ) & \\ {Λ}_{j} = {λ}_{j} + {\sum }_{{k}^{′} ∈ B ( j )} {α}_{{k}^{′} j} & [ 5 ]\end{matrix}$$

Step 5 (calculation of the temporary estimated word): following equation 6 is calculated for jε[1,J].

$$\begin{matrix}( Equation 6 ) & \\ {\hat{c}}_{j} = \{ \begin{matrix}0 & sign ( {Λ}_{j} ) = 1 holds \\ 1 & sign ( {Λ}_{j} ) = - 1 holds\end{matrix} & [ 6 ]\end{matrix}$$

Step 6 (parity check): whether the temporary estimated word corresponds to a codeword is checked. If (ĉ₁ to ĉ_{J}) meets following equation 7, (ĉ₁ to ĉ_{J}) is outputted as the estimated word, and the algorithm is finished.

[7]

(ĉ₁, . . . , ĉ_{J})H^{T}=0 (Equation 7)

Step 7 (the count of the number of repetitions): if q<Q holds, q is incremented, and the flow returns to step 2. If q=Q holds, (ĉ₁ to ĉ_{J}) is outputted as the estimated word, and the algorithm is finished.

Here, LDPC decoder 217 differs from conventional min-sum decoding in executing equation 3 in step 2. By multiplying sign (eₖ) in equation 3, it is possible to decode an LDPC code defined by the parity check matrix H using the submatrix Hn and multiplication result Ep alone. This processing is possible with the present embodiment because there is no error in the received primary BCH information sequence Spr.

Decoder 212 divides the information sequence (=[Snr Pcr]) acquired after decoding, into the non-primary BCH information sequence Our and parity bit Pcr, and outputs only the non-primary BCH information sequence Snr.

Demodulator 207 demodulates and outputs an SDCH received symbol Xdr to deinterleaver 210. Deinterleaver 210 outputs an SDCH encoded sequence Cdr. Decoder 213 decodes the encoded sequence Cdr, which is encoded at a predetermined code length and coding rate, to acquire the SDCH information sequence Sdr.

As described above, according to the present embodiment, transmitting apparatus 100 (i.e. base station) encodes the non-primary BCH information sequence Sn at a long code length by taking the primary BCH information sequence Sp into account, and receiving apparatus 200 (i.e. mobile terminal) decodes the non-primary BCH information sequence Snr at a long code length using the value of the received primary BCH.

By this means, it is possible to acquire greater coding gain compared to the case where the non-primary BCH alone is encoded, and improve the reception characteristics of the non-primary BCH. That is, it is possible to achieve the object of improving interference robustness in an environment where there is interference. Although, generally, additional information bits are required to increase the code length, the present invention uses a known primary BCH as additional information bits, so that it is possible to increase the code length without increasing or decreasing the number of the non-primary BCH information bits to be transmitted.

Further, receiving apparatus 200 (i.e. mobile terminal) receives and decodes the primary BCH information sequence, and obtains information about the bandwidth used by transmitting apparatus 100 (i.e. base station) and so on, and then receives and decodes the non-primary BCH information sequence, so that it is possible to use the correct primary BCH information sequence when the non-primary BCH is decoded. Consequently, decoder 212 of a short code length of only the non-primary BCH can decode a codeword Cnr that is encoded at a code length taking the primary BCH into account and that matches the non-primary BCH. By so doing, receiving apparatus 200 (i.e. mobile terminal) needs not to have a decoder that supports a long code length, so that it is possible to reduce the circuit scale and save the cost to develop new hardware.

Further, although the channel configuration shown in FIG. 1 is employed with the present embodiment, the present invention is also applicable when other configurations are employed. For example, even when the transmission bands of the primary BCH and non-primary BCH are spaced apart, transmitting apparatus 100 and receiving apparatus 200 according to the present embodiment are applicable by changing the mapping pattern of subcarrier mapping section 110 in FIG. 3 and the demapping pattern in subcarrier demapping section 204 in FIG. 6.

Further, although a configuration has been explained with the present embodiment as an example where transmitting apparatus 100 and receiving apparatus 200 have one transmitting and receiving antenna, respectively, the present invention is also applicable to a multi-input multi-output (MIMO) system that has a plurality of antennas. In this case, the non-primary BCH receives not only inter-sector interference but also interference of different spatially multiplexed streams, so that improving coding gain by the present invention is more advantageous.

Further, the present embodiment employs a configuration where, to encode the non-primary BCH information sequence Sn, the information sequence Sc jointing the primary BCH information sequence Sp and the non-primary BCH information sequence Sn is encoded. However, even when the sequence length of the jointed information sequences Sc is different from the information sequence length of a predetermined code length, it is possible to perform encoding at a long code length by carrying out such operations as zero-padding or puncturing.

For example, when the sequence length of the jointed information sequence Sc is less than the information sequence length of a predetermined code length, encoding processing may be performed by padding zero sequences to the jointed information sequence Sc. In this case, without transmitting zero sequences that are padded, decoding is performed in receiving apparatus 200 by padding zero sequences again to the sequence length of the jointed information sequence Sc. Further, when the sequence length of the jointed information sequence Sc is longer than the information sequence length of a predetermined code length, the sequence length of the jointed information sequence Sc is adjusted to the information sequence length of the predetermined code length by removing (i.e. puncturing) part of the sequence length of the primary BCH information sequence Sp. At this time, by sharing the rule of puncturing between transmitting apparatus 100 and receiving apparatus 200, receiving apparatus 200 can puncture the primary BCH information sequence Sp based on the same rule of puncturing and utilize the information sequence Sp to decode the non-primary BCH information sequence Sn. For example, the following rule may be used as the rule at this time.
The L bits from the head of Sp are punctured (where L is the number of bits exceeding the information sequence length of a predetermined code length).
The L bits from the tail of Sp are punctured.
Assuming that the number dividing the information sequence length Kp of Sp by L is M, Sp is punctured every other M bits.

### Embodiment 2

With the present embodiment, the present invention is applied to the layered transmission scheme used in terrestrial digital data broadcasting. The present embodiment will be explained below with reference to an example of the layered transmission scheme used in terrestrial digital data broadcasting.

FIG. 9 shows an image of the layered transmission scheme in terrestrial digital data broadcasting. With the example of FIG. 9, there are two layers of data layers and three segments are transmitted at the same time in these two layers. The three-segment format enables layered transmission of transmitting in two layers of varying transmission characteristics at the same time using one center OFDM segment and the other two OFDM segments. Each layer can specify the carrier modulation scheme, the coding rate of an inner symbol and parameters such as the time interleaving length, on a per layer basis. Further, as to the center OFDM segment, part of service can be received using a receiver that receives only signals of a one-segment format by performing a frequency interleaving only in this center OFDM segment.

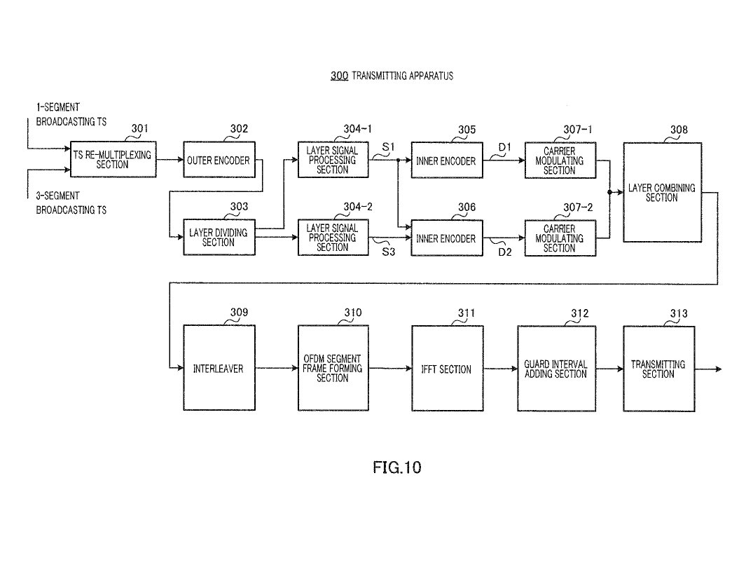

FIG. 10 shows the configuration of a transmitting apparatus that performs layered transmission. Transmitting apparatus 300 is provided in the base station. TS re-multiplexing section 301 multiplexes a TS (Transport Stream) of one-segment broadcasting and a TS of three-segment broadcasting. Outer encoder 302 performs error correction coding of the multiplexed TS. Layer dividing section 303 divides again the outer-encoded sequence into the one-segment broadcasting TS and the three-segment broadcasting TS, and outputs the one-segment broadcasting TS and the three-segment broadcasting TS to layered signal processing section 304-1 and layered signal processing section 304-2, respectively.

Layered signal processing sections 304-1 and 304-2 perform processing such as energy diffusion processing, delay correction and byte interleaving, with respect to the input one-segment broadcasting TS and three-segment broadcasting TS, respectively.

Inner encoder 305 receives as input the one-segment broadcasting TS (S1) subjected to layer processing, performs error correction coding of the one-segment broadcasting TS (S1) and outputs an encoded sequence D1.

To encode the three-segment broadcasting TS, inner encoder 306 performs encoding utilizing the one-segment broadcasting TS.

FIG. 11 shows the configuration of inner encoder 306. Inner encoder 306 has bit jointing section 306-1, inner encoding section 306-2 and codeword separating section 306-3. Inner encoder 306 inputs the three-segment broadcasting TS (S3) and the one-segment broadcasting TS (S1) to bit jointing section 306-1, and outputs a sequence jointing these TS's. Inner encoder 306-2 inner-encodes the jointed sequence to output an encoded sequence D3 formed with the three-segment broadcasting encoded sequence S3′, one-segment broadcasting encoded sequence 51′ and parity sequence Pn (i.e. parity bits). Out of the three-segment broadcasting encoded sequence S3′, one-segment broadcasting encoded sequence S1′ and parity sequence Pn (i.e. parity bits) acquired in inner encoding section 306-2, codeword separating section 306-3 does not output the one-segment broadcasting encoded sequence S1′, and outputs the three-segment broadcasting encoded sequence S3′ and parity sequence Pn (i.e. parity bits) as the encoded sequence D2.

This will be explained in detail. Here, an information sequence of the length K1 is S1 which is part of the one-segment broadcasting TS, and an information sequence of the length K3 is S3 which is part of the three-segment broadcasting TS. Inner encoding section 306-2 performs block coding. An LDPC code may be an example of the block coding scheme that can be used at this time. The encoded sequence D3 acquired in inner coding section 306-2 is represented by following equation 8.

[8]

D3=[S1′S3′Pn] (Equation 8)

Of this encoded sequence D3, the encoded sequence S1 is information that is not required to transmit the three-segment broadcasting TS and therefore is discarded by codeword separating section 306-3, and inner encoder 306 transmits an encoded sequence D2=[S3′ Pn].

By so doing, inner encoder 306 can encode the information sequence S3 at a long code length compared to the case where the information sequence S3 alone is encoded. As a result, the coding gain upon reception increases and the received quality (i.e. the error rate characteristics) of the three-segment broadcasting TS improves.

Particularly, to perform layered transmission in terrestrial digital data broadcasting, information of a higher bit rate (e.g. high definition video image) is transmitted in an upper layer and, therefore, the upper layer uses a modulation scheme such as 64 QAM that has a high M-ary modulation value but frequently causes error. The present invention can increase the coding gain of an upper layer and realize robustness with respect to errors, and can provide quality transmission.

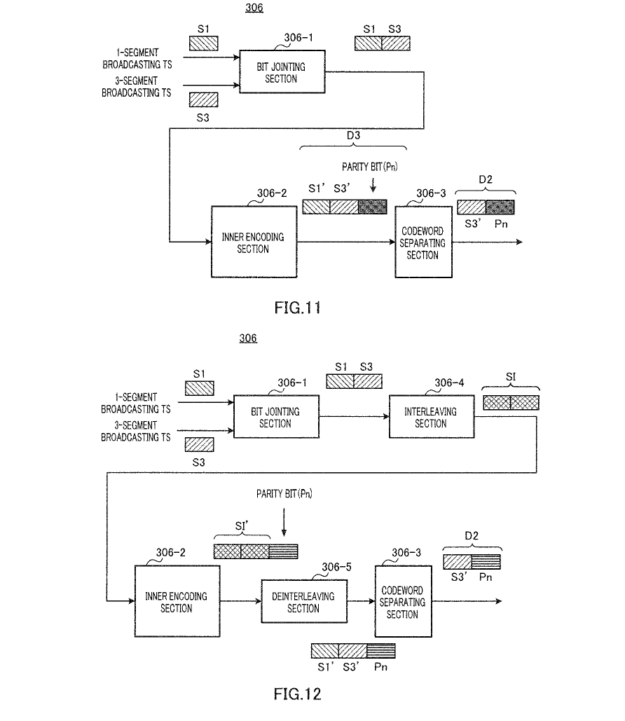

FIG. 12 shows another configuration example of inner encoder 306. In comparison with the configuration in FIG. 11, in inner encoder 306 in FIG. 12, interleaving section 306-4 is provided between bit jointing section 306-1 and inner encoding section 306-2, and deinterleaving section 306-5 is provided between inner encoding section 306-2 and codeword separating section 306-3. That is, inner encoding section 306-2 encodes the interleaved, jointed sequence S1. Deinterleaving section 306-5 performs deinterleaving processing of only the encoded sequences S1′ and S3′ out of the encoded sequences S1′ and S3′ and parity bit Pn.

Back in FIG. 10, explanation of the overall configuration of transmitting apparatus 300 will be continued.

Carrier modulating sections 307-1 and 307-2 bit-interleave the encoded sequences D1 and D2, respectively, and modulate the encoded sequences D1 and D2 according to digital modulation schemes matching the layers, such as PSK, QAM and so on. Layer combining section 308 combines the one-segment broadcasting TS and three-segment broadcasting TS.

Interleaver 309 time/frequency-interleaves the combined symbol sequence. OFDM segment frame forming section 310 assigns the interleaved symbol sequence to the OFDM segment frame.

IFFT section 311 performs IFFT processing to perform OFDM modulation. Guard interval adding section 312 adds a guard interval of a predetermined length to the head of each OFDM symbol. Transmitting section 313 performs signal transmission processing such as D/A conversion, frequency conversion and amplification of a modulated multicarrier signal with a guard interval, and supplies the signal after transmission processing, to the transmitting antenna.

As described above, according to the present embodiment, an upper layer information sequence S3 is encoded at a long code length taking a lower layer information sequence S1 into account, so that it is possible to acquire greater coding gain compared to the case where the upper layer alone is encoded and improve the reception characteristics of the upper layer. Further, generally, when the code length is increased, additional information bits are required. However, the known lower layer bits are used as additional information bits with the present embodiment, so that it is possible to increase the code length without increasing and decreasing the number of upper layer information bits that are transmitted.

Further, although three-segment broadcasting in terrestrial digital data broadcasting has been explained as an example, the present invention is applicable to a wider range of layered transmission schemes such as thirteen-segment broadcasting.

Furthermore, although the present embodiment has been explained assuming that the number of data layers is two, the number layers may be three or more. That is to say, to encode an upper layer information sequence, the upper layer information sequence only needs to be jointed with lower layer information sequences and then encoded. Consequently, it is possible to secure a long code length and increase coding gain upon decoding.

### Embodiment 3

With the present embodiment, the principle of jointing a plurality of information sequences and encoding the jointed sequence according to the present invention is applied to hybrid ARQ (Automatic Repeat Quest). With the present embodiment, to retransmit an error correction encoded block that has produced an error, a plurality of error correction encoded blocks are combined to form an error correction code word block to be retransmitted at a long code length compared to upon a previous transmission, and transmit only the parity portion of the error correction codeword block.

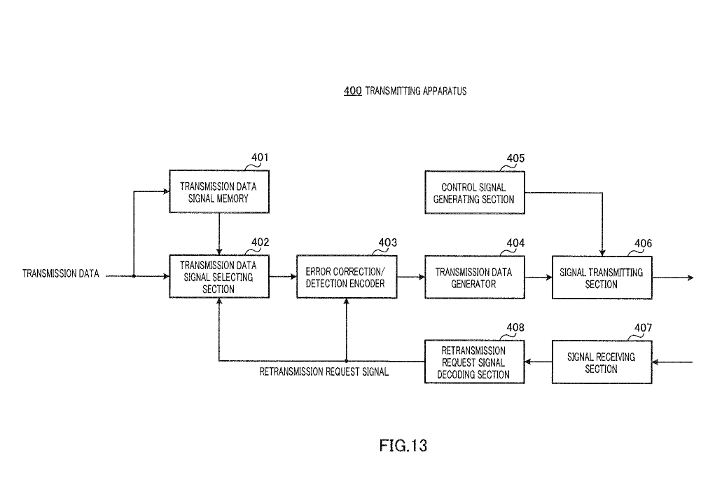

FIG. 13 shows the configuration of the transmitting apparatus according to the present embodiment.

Transmitting apparatus 400 inputs transmission data signals to transmission data signal memory 401 and transmission data signal selecting section 402. Transmission data signal memory 401 stores the transmission data signals inputted.

Transmission data signal selecting section 402 outputs transmission data signals newly inputted, to error correction/detection encoder 403 upon the initial transmission, and outputs transmission data stored in transmission data signal memory 401, to error correction/detection encoder 403 upon retransmission.

Here, error correction/detection encoder 403 is configured to support error correction codeword blocks having J kinds of lengths (N₁, N₂, . . . , N_{J}, where N₁<N₂< . . . <Nⱼ) and encoding involving I kinds of coding rates (R₁, R₂, . . . , R_{I}, where R₁<R₂< . . . <R_{I}). Error correction/detection encoder 403 performs error correction coding and error detection coding of data signals at a predetermined code length Nⱼ and coding rate Rᵢ. The coding scheme at this time may utilize the coding scheme for assigning error detection parity bits such as CRC (Cyclic Redundancy Check) bits to a codeword that is subjected to LDPC-coding, convolution coding or turbo coding. Particularly, thanks to the configuration of an LDPC code, error correction coding and error detection coding can be performed at the same time using an LDPC code, and a configuration using an LDPC code will be explained with the present embodiment as an example.

First, error correction/detection encoder 403 divides transmission data Sᵢ (i=1, 2, . . . , Ns) into N_{B} blocks each formed with Kᵢ bits. Hereinafter, these blocks will be referred to as “error correction codeword blocks.” Further, when Nₛ/N_{B} does not produce an integer, some bits are added to the tail of Sᵢ to adjust the number of transmission bits such that Nₛ/N_{B} produces an integer. Next, error correction/detection encoder 403 performs LDPC coding on a per error correction codeword block basis. Here, LDPC coding is performed by a random method meeting following equation 9 assuming that an error correction codeword block formed with Nⱼ bits is C and an LDPC code parity check matrix of the Mⱼ×Nⱼ size is H₁.

[9]

H₁C=0 (Equation 9)

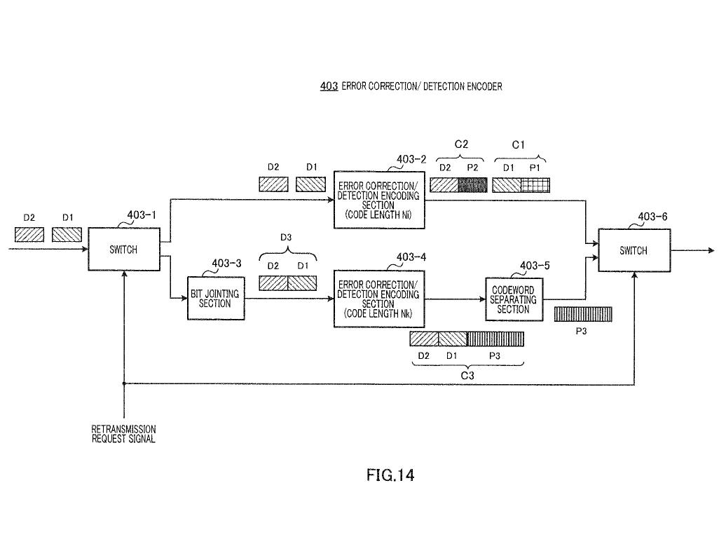

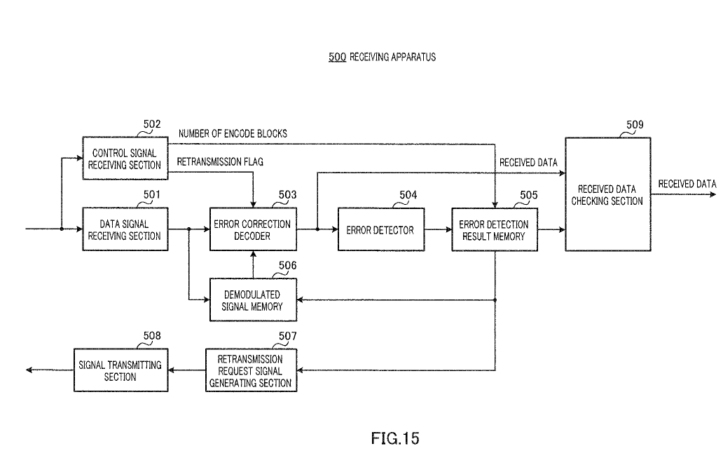

FIG. 14 shows the configuration of error correction/detection encoder 403 according to the present embodiment. Error correction/detection encoder 403 inputs data D1 and D2 outputted from transmission data signal selecting section 402, to switch 403-1. When a retransmission request signal does not request retransmission, switch 403-1 outputs initial transmission data D1 and D2 to error correction/detection encoding section 403-2. By contrast with this, when a retransmission request signal requests retransmission, switch 403-1 outputs retransmission data D1 and D2 stored in transmission data signal memory 401, to bit jointing section 403-3.

Bit jointing section 403-3 forms data D3 jointing retransmission data D1 and D2, and outputs this data to error correction/detection encoding section 403-4.

Error correction/detection encoding section 403-2 encodes initial transmission data D1 and D2 at the code length Nᵢ to form and output encoded data C1=[D1 P1] and C2=[D2 P2] to switch 403-6. Here, P1 and P2 represent parity bits acquired after encoding.

Error correction/detection encoding section 403-4 encodes retransmission data D3 jointing retransmission data D1 and D2 at the code length Nₖ longer than the code length Nᵢ used upon the initial transmission, to form and output encoded data C3[D3 P3](=[D1 D2 P3]), to codeword separating section 403-5. Here, P3 represents the parity bit acquired after encoding.

Codeword separating section 403-5 separates the parity bit P3 from inputted encoded data C3, and outputs only the parity bit P3.

When a retransmission request signal does not request retransmission, switch 403-6 selects encoded data C1 and C2 from error correction/detection encoding section 403-2, and outputs encoded data C1 and C2. By contrast with this, when a retransmission request signal requests retransmission, switch 403-6 selects the parity bit P3 from codeword separating section 403-5, and outputs the parity bit P3.

In this way, to retransmit an error correction encoded block that has produced an error, error correction/detection encoder 403 combines a plurality of error correction encoded blocks to form an error correction codeword block that is retransmitted at a code length longer than the code length used upon a previous transmission, and outputs only the parity portion of the error correction codeword block.

Transmission data signal generator 404 performs predetermined modulation processing of signals outputted from error correction/detection encoder 403 to generate and output transmission data signals to signal transmitting section 406.

Control signal generating section 405 generates a control signal configured with: the code length and coding rate of an LDPC code; the number of error correction codeword blocks N_{B}; a retransmission flag showing whether each error correction encoded block has been retransmitted or transmitted for the first time; a modulation scheme; and a preamble signal for synchronization and channel estimation, and outputs this control signal to transmitting section 406. Signal transmitting section 406 arranges the control signal and data signal in predetermined positions in the transmission frame, and converts the transmission frame into a radio signal to generate a transmission signal and transmit the transmission signal from the antenna.

Further, in transmitting apparatus 400, signal receiving section 407 receives the retransmission request signal transmitted from receiving apparatus 500 of FIG. 15 (described later). Retransmission request signal decoding section 408 performs predetermined demodulation/decoding processing of the received retransmission request signal, restores the error detection result included in the retransmission request signal and outputs this error detection result (represented as a retransmission request signal in figures) to transmission data signal selecting section 402 and error correction/detection encoder 403.

FIG. 15 shows the configuration of the receiving apparatus that receives signals transmitted from transmitting apparatus 400. Receiving apparatus 500 inputs signals received at the antenna, to data signal receiving section 501 and control signal receiving section 502.

Control signal receiving section 502 demodulates and decodes the control signal block positioned at the head, middle or tail of a packet. Here, the control signal includes the number of error correction codeword blocks N_{B}, a retransmission flag, and the code length and coding rate of the error correction codeword.

Control signal receiving section 502 outputs the number of error correction codeword blocks N_{B}, to error detection result memory 505. Further, control signal receiving section 502 transmits the retransmission flag to error correction decoder 503. Further, although a control signal includes the modulation scheme of a received signal and a preamble signal for synchronization and channel estimation, these are not directly related to the present invention, and, therefore, explanation thereof will be omitted.

When an initial transmission signal is received, data signal receiving section 501 receives a data signal configured with N_{B} error codeword blocks. Further, when a retransmission signal is received, data signal receiving section 501 receives a data signal configured with N_{P} parity blocks. Data signal receiving section 501 outputs the received data signal to error correction decoder 503. Further, data signal receiving section 501 outputs the received data signal to demodulated signal memory 506 to use for processing upon retransmission. Demodulated signal memory 506 stores data signals on a per applicable error correction codeword block basis.

Error correction decoder 503 performs error correction decoding processing in order from the error correction codeword block at the head. Based on a retransmission flag, error correction decoder 503 performs error correction decoding processing using received data alone when an error correction codeword block to be decoded is a block of the initial transmission. By contrast with this, when an error correction codeword block to be decoded is a retransmission block, error correction decoder 503 performs error correction decoding processing utilizing the received data that is transmitted previously and that is stored in demodulated signal memory 506 and received data that is received this time. Further, in case of the initial transmission, the retransmission flag shows “initial transmission” in all error correction codeword blocks, so that error correction decoding processing is performed using received data alone.

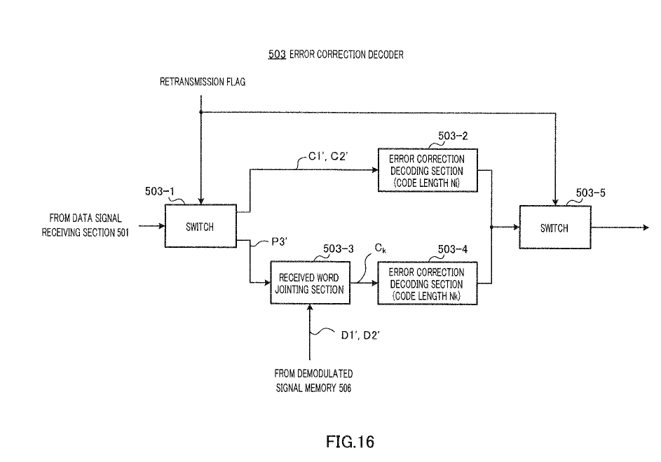

FIG. 16 shows the configuration of error correction decoder 503 according to the present embodiment. Error correction decoder 503 inputs data signals outputted from data signal receiving section 501, to switch 503-1. When the retransmission flag does not indicate retransmission, switch 503-1 outputs data signals, that is, encoded data C1′=[D1′ P1′] and C2′=[D2′ P2′] of the initial transmission, to error correction decoding section 503-2 based on the retransmission flag.

By contrast with this, when the retransmission flag indicates retransmission, switch 503-1 outputs the data signal, that is, the parity bit P3′ that is retransmitted, to received word jointing section 503-3.

Received word jointing section 503-3 joints, to the parity bit P3′, received data, that is, encoded data D1′ and D2′, that is received previously and that is stored in demodulated signal memory 506 as shown in following equation 10, and outputs the jointed codeword Ck to subsequent error correction decoding section 503-4.

[10]

Ck=[D1′D2′P3] (Equation 10)

Error correction decoding section 503-4 performs error correction decoding of the jointed codeword Ck of the length Nk at the code length Nk longer than the code length Ni of error correction decoding section 503-2.

Switch 503-5 outputs a decoding result in error correction decoding 503-2 when the retransmission flag does not indicate retransmission, and outputs a decoding result in error correction decoding section 503-2 when the retransmission flag indicates retransmission.

Error correction decoder 503 outputs received data that is subjected to error correction decoding, to error detector 504 and received data checking section 509. Then, error correction decoder 503 performs error correction decoding processing of the next error correction codeword block.

Error detector 504 performs an error detection of the error correction codeword block that is subjected to error correction decoding. In case of an LDPC code, an error detection is performed depending on whether or not the above-described parity check matrix H1 and decoded error correction codeword block C′ meet following equation 11.

[11]

H₁C′=0 (Equation 11)

When there is an error in the decoded error correction codeword block C′, the right side of equation 11 does not become a zero vector. Error detector 504 transmits an encoded error detection result to error detection result memory 505 and performs an error detection of the next error correction codeword block. Here, a method of transmitting “0” when there is no error and transmitting “1” when there is an error, can be utilized as an example of encoding an error detection result.

Error detection result memory 505 has N_{B} memory addresses and sequentially stores the error detection result of each error correction codeword block outputted from error detector 504. Error detection result memory 505 stores the error detection result of the n_{B}-th error correction codeword block in the n_{B}-th memory address.

The operation in case where error detections of all N_{B} error correction codeword blocks are finished and all detection results are “0,” will be explained.

In this case, error detection result memory 505 transmits a memory data control signal to command removal of received data of each error correction codeword block stored in demodulated signal memory 506. Demodulated signal memory 506 removes stored received data based on the memory data control signal outputted from error detection result memory 505.

Further, error detection result memory 505 outputs the error detection result to received data checking section 509. Received data checking section 509 checks received data and the error detection result, and outputs received data corresponding to the error correction codeword block without an error, to the subsequent stage. Further, in this case, all detection results are “0” and, consequently, all received data is outputted.

Next, the operation in case where an error correction codeword block as the error detection result showing “1,” will be explained.

In this case, when an error correction codeword block as the error detection result showing “1” is detected, error detection result memory 505 outputs a memory data control signal to command demodulated signal memory 506 to remove received data of an error correction codeword block as an error correction result showing “0” and hold received data of an error correction codeword block as an error detection result showing “1.”

Further, error detection result memory 505 transmits a retransmission block command signal to command retransmission request signal generating section 507 to retransmit the error correction codeword block as the error detection result showing “1.”

Further, error detection result memory 505 outputs the error detection result of each error correction codeword block, to received data checking section 509. Received data checking section 509 checks received data against the error detection result, and outputs only received data corresponding to the error correction codeword block without an error, to the subsequent stage.

Demodulated signal memory 506 removes received data of the error correction codeword block as the error detection result showing “0,” based on the memory data control signal. Further, demodulated signal memory 506 holds received data of the error correction codeword block as the error detection result showing “1.” Retransmission request signal generating section 507 generates a retransmission request signal describing an error correction codeword block to retransmit, based on the retransmission block command signal transmitted from error detection result memory 505, and outputs the retransmission request signal to signal transmitting section 508. Signal transmitting section 508 performs predetermined encoding processing and modulation processing of the retransmission request signal, and transmits the retransmission request signal to transmitting apparatus 400.

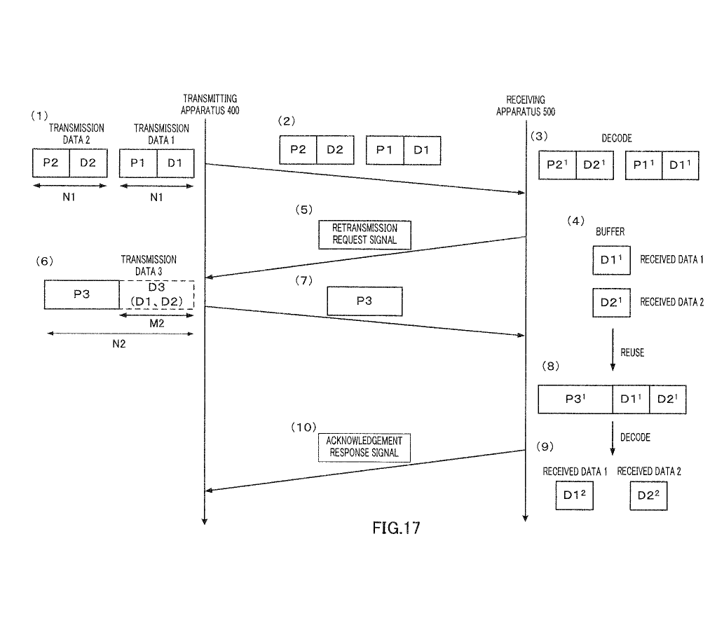

The flowchart of transmitting and receiving signals according to the present embodiment described above, will be explained using FIG. 17 as an example. With this example, transmitting apparatus 400 transmits transmission data D1 and D2.

(1) Transmitting apparatus 400 encodes transmission data D1 and D2 at the code length N1 and coding rate R1, and acquires the error correction codeword blocks C1=[D1 P1] and C2=[D2 P2]. (2) Transmitting apparatus 400 transmits error correction codeword blocks C1 and C2 to receiving apparatus 500. (3) Receiving apparatus 500 receives the error correction codeword blocks C11 and C21 that have been transmitted through communication channels, and performs error correction decoding of the error correction codeword blocks C11 and C21. Receiving apparatus 500 performs an error detection to detect whether there is an error in received data D1¹ and D2¹.

An example will be explained below where there are errors in received data D1¹ and D2¹. (4) Receiving apparatus 500 accumulates received data D1′ and D2′ before error correction decoding, in demodulated signal memory 506. (5) Receiving apparatus 500 transmits a retransmission request signal that requests retransmission of transmission data D1 and D2, to transmitting apparatus 400. (6) When receiving the retransmission request signal, transmitting apparatus 400 encodes D3=[D1 D2] jointing transmission data D1 and D2, at the code length N2 (where N1<N2) and coding rate R2, and acquires an error correction codeword block C3=[D3 P3].

(7) Transmitting apparatus 400 transmits only the parity block P3 acquired after encoding, to receiving apparatus 500. (8) Receiving apparatus 500 receives the parity block P3¹ that has been transmitted through a communication channel, performs error correction decoding using D1¹, D2¹ and P3¹ accumulated in demodulated signal memory 506, and performs an error detection of the decoding result. (9) If there is no error in the decoding result, receiving apparatus 500 transmits D1² and D2² acquired after the decoding processing of (8), to the subsequent stage as received data. (10) Receiving apparatus 500 transmits an acknowledgement signal showing that decoding can be performed correctly, to transmitting apparatus 400.

As described above, according to the present embodiment, to retransmit an error correction codeword block that has produced an error, encoding is performed at a code length longer than the code length that is previously used, and only the parity portion of the error correction codeword block is transmitted, so that it is possible to perform encoding at a long code length of great error correction performance upon retransmission and reduce the communication band upon retransmission by transmitting only the parity portion of the error correction codeword block.

Further, although transmitting apparatus 400 transmits only the parity block with the present embodiment, the entire error correction codeword block may be transmitted in addition to the parity block. By so doing, a new error correction codeword block that is newly transmitted when decoding is performed in receiving apparatus 500 can be utilized entirely, so that gain upon decoding increases.

### Embodiment 4

With the present embodiment, an encoder that encodes data jointing a plurality of items of layer data will be explained with reference to the drawings. A case will be explained with the present embodiment as an example where a low density parity check code (LDPC code) is used for the coding scheme and the number of layers is two.

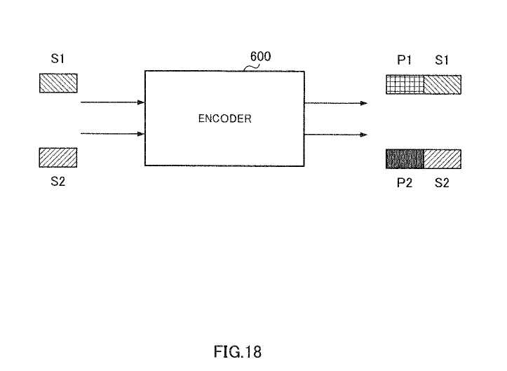

FIG. 18 shows the relationship between input and output of encoder 600. Encoder 600 receives as input first layer data S1 and second layer data S2, and outputs the first layer data S1, first layer parity P1, second layer data S2 and the second layer parity P2. Hereinafter, assume that the second layer data S2 is an upper layer data of the first layer data S1.

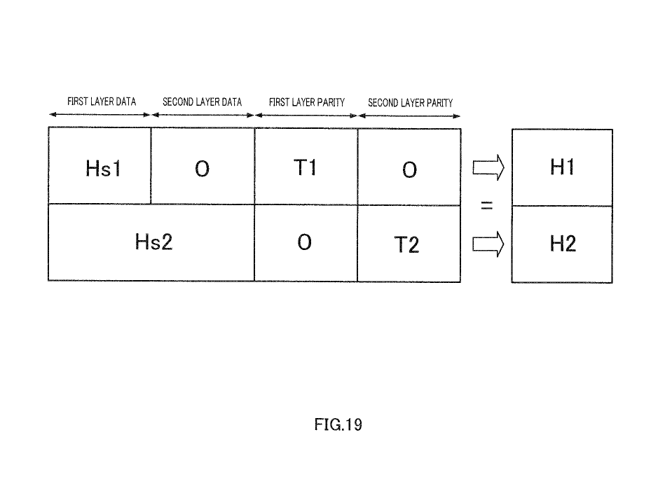

Encoder 600 performs encoding according to an LDPC code defined by the parity check matrix H shown in FIG. 19. The parity check matrix H employs a configuration that can be divided into a submatrix H1 and a submatrix H2.

The submatrix H1 is formed with the parity check matrix Hs1 corresponding to the first layer data S1 and the parity check matrix T1 corresponding to the first layer parity P1. Further, in the submatrix H1, the portion corresponding to the second layer data S2 and the portion corresponding to the second layer parity P2 are formed with zero matrices.

The submatrix H2 is formed with Hs2 corresponding to the first layer data S1 and second layer data S2 and the parity check matrix T2 corresponding to the second layer parity P2. Further, the portion corresponding to the first layer parity P1 is formed with the zero matrix.

Encoder 600 finds the first layer parity P1 using the first layer data S1 and submatrix that is represented as Hs1 in the parity check matrix H. Further, encoder 600 finds the second layer parity P2 using the first layer data S1, second layer data S2 and submatrix that is represented as Hs2 in the parity check matrix.

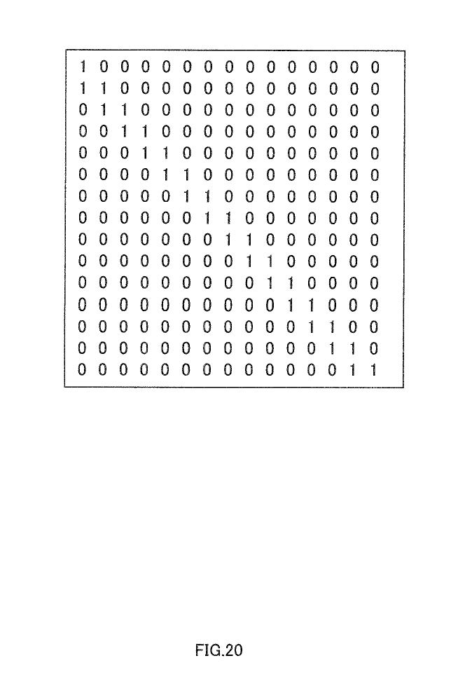

The specific configuration example of encoder 600 will be explained using a case as an example where the parity check matrix T1 corresponding to the first layer parity and the parity check matrix T2 corresponding to the second layer parity each employ the configuration shown in FIG. 20.

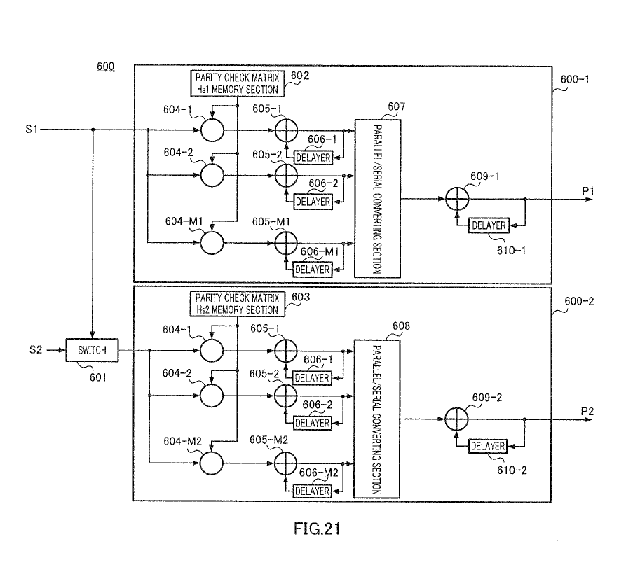

With the check matrices T1 and T2, the element in the first column of the first row is 1 and, in the second row or thereafter, the elements in the i−1-th column and the i-th column of the i-th row are 1. At this time, the submatrices H1 and H2 may be regarded as RA (Repeat-Accumulate) codes. Therefore, the internal configuration of encoder 600 can be made the configuration shown in FIG. 21. Further, in FIG. 21, M1 represents the number of rows in the submatrix H1, and M2 represents the number of rows in the submatrix H2.

Encoder 600 in FIG. 21 is constituted by switch 601, parity check matrix Hs1 memory section 602, parity check matrix Hs2 memory section 603, weight multipliers 604-1 to 604-M1 and 604-1 to 604-M2, mod 2 adders 605-1 to 605-M1, 605-1 to 605-M2, 609-1 and 609-2, delayers 606-1 to 606-M1, 606-1 to 606-M2, 610-1 and 610-2 and parallel/serial converting sections 607 and 608.

Hereinafter, parity check matrix Hs1 memory section 602, weight multipliers 604-1 to 604-M1, mod 2 adders 605-1 to 605-M1 and 609-1, delayers 606-1 to 606-M1 and 610-1 and serial/parallel converting section 607 generate the first layer parity P1. These components that generate the first layer parity P1 are referred to as “first layer parity generating section 600-1.” Furthermore, parity check matrix Hs2 memory section 603, weight multipliers 604-1 to 604-M2, mod 2 adders 605-1 to 605-M2 and 609-2, delayers 606-1 to 606-M2 and 610-2 and serial/parallel converting section 608 generate the second layer parity P2. These components that generate the second layer parity P2 are referred to as “second layer parity generating section 600-2.”

Switch 601 switches data to be inputted in second layer parity generating section 600-2.

Parity check matrix Hs1 memory section 602 stores the arrangement of “1” and “0” in the parity check matrix Hs1, and outputs weights according to this arrangement, to weight multipliers 604-1 to 604-M1. Weight multipliers 604-1 to 604-M1 multiply the first layer data S1 and the weights.

mod 2 adders 605-1 to 605-M1 mod 2-add outputs of weight multipliers 604-1 to 604-M1 and outputs of mod 2 adders 605-1 to 605-M1 that are outputted one stage before delayers 606-1 to 605-M1, and output the results to parallel/serial converting section 607 and delayers 606-1 to 606-M1.

Parallel/serial converting section 607 holds the outputs of mod 2 adders 605-1 to 605-M1 while the first layer data S1 is being inputted and, after having received the first layer data S1 as input, output results of the mod 2 adders are sequentially outputted in order from mod 2 adder 605-1, to mod 2 adder 609-1.

mod 2 adder 609-1 mod 2-adds the output of parallel/serial converting section 607 and the output of mod 2 adder 609-1 that are outputted one stage before delayer 610-1, and outputs the result as the first layer parity P1.

As to second layer parity generating section 600-2 that generates the second layer parity P2, each processing section functions in the same way as first layer parity generating section 600-1 that finds the first layer parity P1. The difference is that parity check matrix Hs2 memory section 603 stores the arrangement of “1” and “0” in the parity check matrix Hs2 and, after parallel/serial converting section 608 receives as input the first layer data S1 and second layer data S2, output results of mod 2 adders are sequentially outputted in order from the output result of mod 2 adder 605-1, to mod 2 adder 609-2.

By so doing, encoder 600 can encode not only the second layer data S2 but also the first layer data S1 when finding the second layer parity P2. Consequently, the code length for encoding second layer data increases by the code length of the first layer data S1, so that it is possible to improve the error robustness of the second layer data.

As described above, encoder 600 receives as input the first layer data S1 and second layer data S2, and outputs the first layer data S1, first layer parity data P1, second layer data S2 and second layer parity P2.

Further, encoder 600 performs encoding using a single parity check matrix H shown in FIG. 19, so that it is possible to acquire the first layer parity P1 and second layer parity P2 at the same time.

Further, although a case has been explained so far where encoder 600 encodes two layers of data using the parity check matrix H in FIG. 19, the essential requirement is that the parity check matrix H is formed with the submatrix H1 that generates the first layer parity P1 only from the first layer data S1, and the submatrix H2 that generates the second layer parity P2 from the first layer data S1 and second layer data S2, and random check matrices may be used for the submatrices H1 and H2.

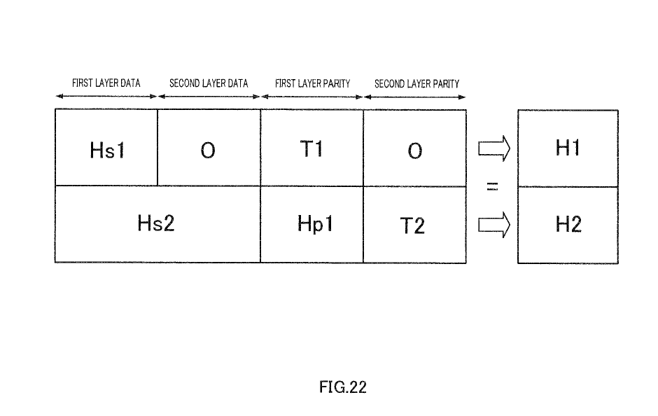

Further, the parity check matrix H may include the submatrix H1 that generates the first layer parity P1 only from the first layer data S1, and the submatrix H2 that generates the second layer parity P2 from the first layer parity P1. The parity check matrix H in this case is shown in FIG. 22. While the column corresponding to the first layer parity P1 is the zero matrix with the submatrix H2 in FIG. 19, there is the parity check matrix Hp1 corresponding to the first layer parity P1 with the submatrix H2 in FIG. 22.

By providing the configuration in FIG. 22, when the second layer data S2 is encoded, encoding can be performed at a code length that is increased by the code length of the first layer parity P1 in addition to the code length of the first layer data S1, so that it is possible to improve the error robustness of the second layer data S2.

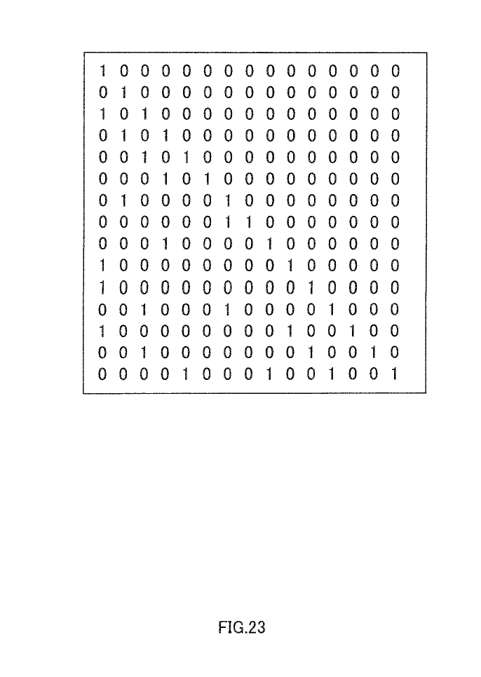

Further, although a case has been explained so far where the parity check matrix T1 corresponding to the first layer parity and the parity check matrix T2 corresponding to the second layer parity employ the configuration shown in FIG. 20, the present invention is not limited to this and, as shown in FIG. 23 for example, a lower triangular matrix may be used for the parity check matrix T1 or T2. By so doing, the parity check matrix H includes the submatrix H1 that generates the first layer parity P1 only from the first layer data S1, and the submatrix H2 that generates the second layer parity P2 from the first layer data S1, second layer data S2 and first layer parity P1.

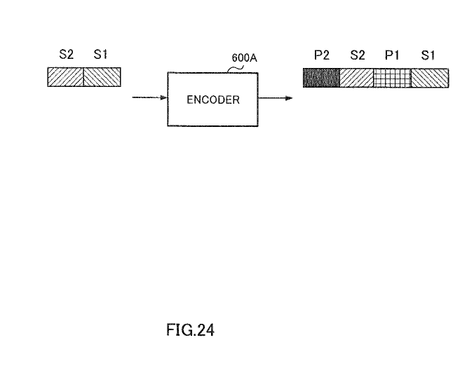

Although a case has been explained so far where encoder 600 receives as input the first layer data S1 and second layer data S2 in parallel, and outputs the first layer data S1 and first layer parity P1, and the second layer data S2 and second layer parity P2 in parallel, respectively, the present invention can provide the same advantage by, as shown in FIG. 24, performing encoding using the parity check matrix H in encoder 600A that receives as input the first layer data S1, first layer parity P1, second layer data S2 and second layer parity P2 in series.

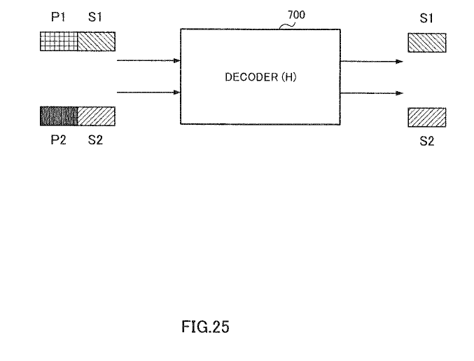

Next, a decoder that decodes a codeword encoded using the parity check matrix H, will be explained. FIG. 25 shows the configuration and the relationship between input and output of the decoder. Decoder (H) 700 in FIG. 25 is an LDPC decoder that receives as input reception likelihoods of the first layer data S1 and first layer parity P1 and reception likelihoods of the second layer data S2 and second layer parity P2, and that performs BP (Belief Propagation) decoding based on the parity check matrix H to acquire the first layer data S1 and second layer data S2.

By performing decoding processing of the first layer data S1 and second layer data S2 collectively using the parity check matrix H in decoder (H) 700, it is possible to acquire decoding results of the first layer data S1 and second layer data S2, at the same time.

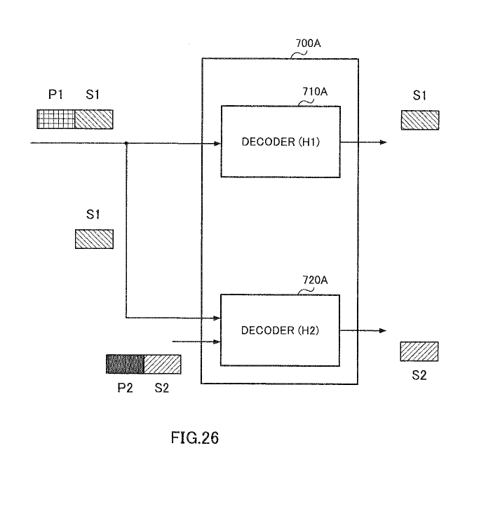

Further, FIG. 26 shows another configuration of the decoder according to the present embodiment. In decoder (H) 700A in FIG. 26, decoder (H1) 710A decodes the first layer data S1 using reception likelihoods of the first layer data S1 and first layer parity P1. Further, decoder (H2) 720A decodes the second layer data S2 using reception likelihoods of the first layer data S1, second layer data S2 and second layer parity P2. By performing such decoding processing, decoding processing of the first layer data S1 and decoding processing of the second layer data S2 can be separated, so that, when the reliability of the reception likelihoods of the second layer data S1 or second layer parity P2 is low due to influences of noise and interference, it is possible to prevent these negative influences upon decoding of the first layer data S1.

Further, even in this case, decoding processing is performed at a code length taking into account the first layer data S1 upon decoding processing of the second layer data S2 and, consequently, the code length is increased, so that it is possible to improve the error robustness of the second layer data S2.

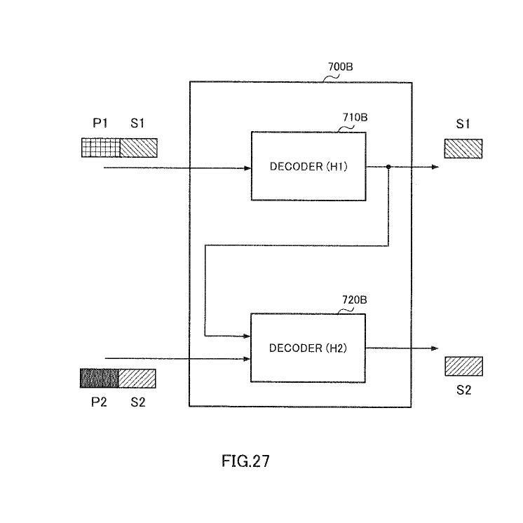

Further, FIG. 27 further shows another configuration of the decoder according to the present embodiment. Decoder (H) 700B in FIG. 27 is constituted by decoder (H1) 710B that performs decoding processing using the submatrix H1 and decoder (H2) 720B that performs decoding processing using the submatrix H2. In decoder (H) 700B, first, decoder (H1) 710B performs decoding processing of the first layer data using the reception likelihoods of the first layer data S1 and first layer parity P1. Then, decoder (H2) 720B performs decoding processing using the reception likelihoods of the first layer data S1 after decoding, second layer data S2 and second layer parity P2, and acquires the decoding result of the second layer data S2. By so doing, decoder (H2) 720B can use the reliable first layer data S1 that is decoded by decoder (H1) 710B, so that it is possible to improve performance of decoding the second layer data.

By performing such decoding processing, decoding processing of the first layer data S1 and decoding processing of the second layer data S2 can be separated, so that, when the reliability of the reception likelihoods of the second layer data S1 or second layer parity P2 is low due to influences of noise and interference, it is possible to prevent these negative influences from spreading to decoding of the first layer data S1.

Further, with this configuration, if the first layer data S1 that is subjected to decoding processing in decoder (H1) 710B is decoded correctly, it is possible to use the same decoding algorithm as decoder 212 according to Embodiment 1 and improve the error robustness of the second layer data S2.

Furthermore, in case where decoder (H) 700B shown in FIG. 27 uses the parity check matrix H that generates the second layer parity P2 using the first layer data S1, first layer parity P1 and second layer data S2 as shown in FIG. 22, decoder (H1) 710B only needs to output the decoding result of the first layer parity P1 in addition to the decoding result of the first layer data S1, to decoder (H2) 720B.

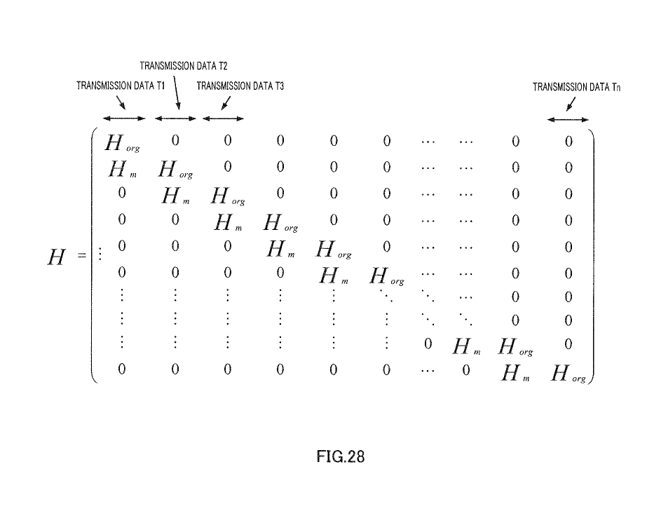

Although a case has been explained so far as an example where the check matrices H shown in FIG. 19 and FIG. 22 are used, the present invention is not limited to this and, for example, the parity check matrix H shown in FIG. 28 may be used. The parity check matrix H shown in FIG. 28 is constituted by the submatrix Horg, which is referred to as a “protograph,” and the submatrix Hm. Each column of the parity check matrix H corresponds to transmission data, and the column which is the n-th column from the left of the parity check matrix H and in which there is the submatrix Horg, corresponds transmission data Tn.

By using such check matrices, to encode the n-th transmission data, transmission data Tn and transmission data T(n−1) can be encoded and the code length can be increased compared to the case where transmission data Tn alone is encoded, so that it is possible to improve error correction performance.

Further, in case where the number of items of transmission data is small, for example, in case where the transmission data length is shorter than the block length of Horg, Horn alone is used to encode transmission data T1 without using Hm, so that it is possible to minimize the amount of extra bits to be transmitted and prevent deterioration in data transmission efficiency.

By contrast with this, when the transmission data length is longer than the block length of Horg, the parity check matrix jointing Hm and Horg is encoded, so that it is possible to provide an advantage of improving received quality.

Further, it is necessary to transmit control information for reporting whether or not encoding is performed using Horg alone or both Horg and Hm, to the communicating party such that the communicating party can switch the parity check matrix to use in decoding.

Furthermore, a parity check matrix of a difference-set cyclic code can be used as Horg. By using a parity check matrix of a difference set cyclic code as Horg, it is possible to acquire good reception performance upon BP decoding thanks to the auto-orthogonality of the difference-set cyclic code.

### Embodiment 5

A case will be explained with the present embodiment where the encoder that encodes the parity check matrix H shown in FIG. 19 is constituted by an encoder that encodes the submatrix H1 and an encoder that encodes the submatrix H2.

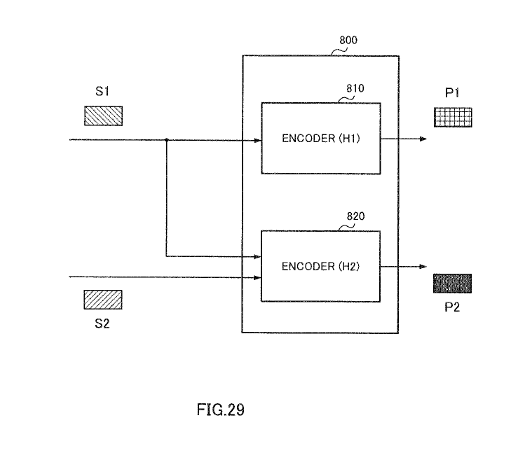

FIG. 29 shows the configuration of the encoder according to the present embodiment. Encoder 800 in FIG. 29 is constituted by encoder (H1) 810 and encoder (H2) 820.

Encoder (H1) 810 generates the first layer parity P1 from the first layer data S1 based on the submatrix H1 of the parity check matrix H. The submatrix H1 is formed with the parity check matrix Hs1 corresponding to the first layer data and the parity check matrix T1 corresponding to the first layer parity.

Further, encoder (H2) 820 generates the second layer parity P2 from the first layer data S1 and the second layer data S2 based on the submatrix H2 of the parity check matrix H. The submatrix H2 is formed with Hs2 corresponding to the first layer data and second layer data and the parity check matrix T2 corresponding to the second layer parity.

By so doing, to encode the second layer data S2, the second layer data P2 can be generated using the first layer data S1 and second layer data S2, so that it is possible to increase the code length of the codeword for the second layer data P2 and improve the error characteristics of the second layer data S2.

As described above, according to the present embodiment, when the parity check matrix H is formed with: the submatrix H1 that is formed with the parity check matrix Hs1 corresponding to the first layer data S1 and the parity check matrix T1 corresponding to the first layer parity P1; and the submatrix H2 that is formed with the parity check matrix Hs2 corresponding to the first layer data S1 and second layer data S2 and the parity check matrix T2 corresponding to the second layer parity P2, encoder 800 has encoder (H1) 810 that generates the first layer parity P1 from the first layer data S1 using the submatrix H1, and encoder (H2) 820 that generates the second layer parity P2 from the first layer data S1 and second layer data S2 using the submatrix H2. In this case, similar to Embodiment 4, it is also possible to improve the error robustness of the second layer data S2.

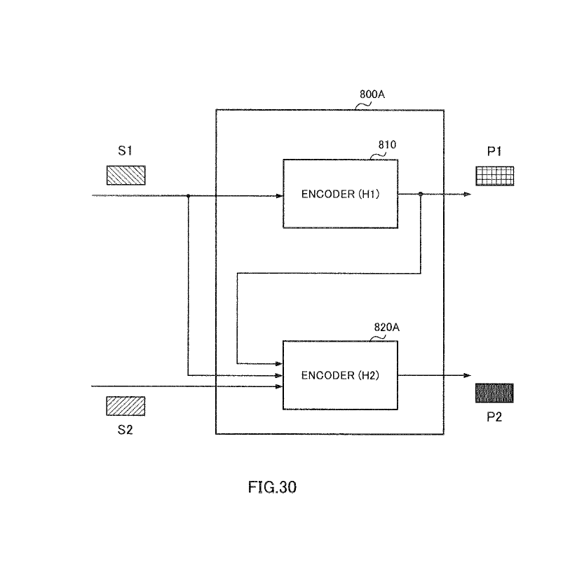

Further, FIG. 30 shows the configuration of an encoder that, to encode the second layer data S2, further uses the first layer parity P1 in addition to the first layer data S1 and second layer data S2. Encoder (H2) 820A of encoder 800A in FIG. 30 receives as input the first layer parity P1 generated by encoder (H1) 810 in addition to the first layer data S1 and second layer data S2. Encoder (H2) 820A generates the second layer parity P2 using these three inputs.

By so doing, to encode the second layer data S2, the first layer data S1 and first layer parity P1 in addition to the second layer data S1 are encoded, so that it is possible to increase the code length and improve the error characteristics of the second layer data S2.

Further, encoder (H1) 810 and encoder (H2) 820A in FIG. 30 are applicable to decoder 211 and decoder 212 of receiving apparatus 200 explained in Embodiment 1.

### Embodiment 6

An anti-interference technique in an encoder that increases the code length by jointing and encoding signals of a plurality of layers and improving the error robustness of data of an upper layer, will be explained with the present embodiment. To be more specific, in case where known bits are inserted in lower layer data and influences of noise and interference upon the lower layer are significant, the anti-interference technique prevents these influences from spreading to decoding of the upper layer.

Decoder (H) 700B in FIG. 27 explained in Embodiment 4 can prevent noise and interference that influence upper layer data, from spreading to decoding of lower layer data. Decoder (H) 700B in FIG. 27 does not use upper layer data (i.e. second layer data S2) to decode lower layer data (i.e. first layer data S1), so that noise and interference that influence the upper layer data are not likely to spread to decoding of the lower layer data.

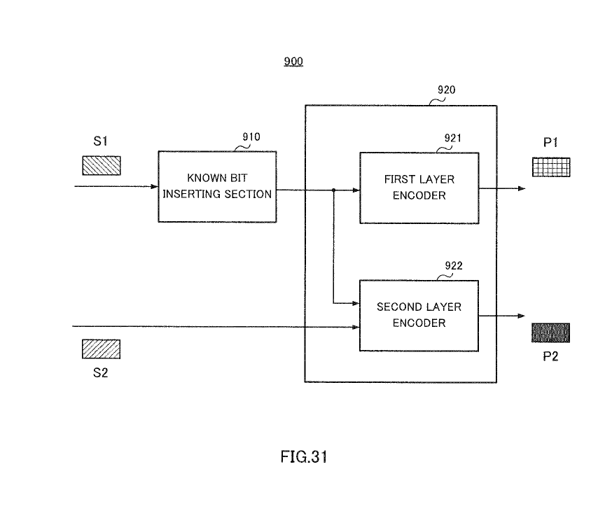

FIG. 31 shows the configuration of the encoder according to the present embodiment. Encoder 900 in FIG. 31 is constituted by known bit inserting section 910 and encoder (H) 920. Further, encoder (H) 920 can use any encoder explained in Embodiment 4 and Embodiment 5. A case will be explained below as an example where encoder (H) 920 is constituted by first layer encoder 921 that generates the first layer parity P1 from the first layer data S1, and second layer encoder 922 that generates the second layer parity P2 from the first layer data S1 and second layer data S2.

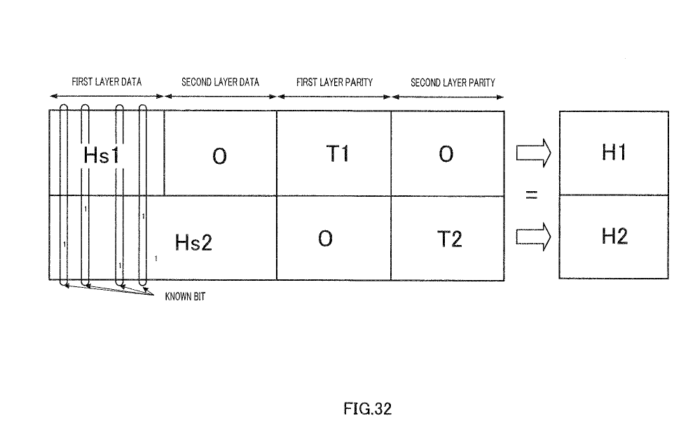

FIG. 32 shows the parity check matrix H used in encoder (H) 920. The parity check matrix H is formed with the submatrix H1 used to find the first layer parity P1 from the first layer data S1, and the submatrix H2 used to generate the second layer parity P2 from the first layer data S1 and second layer data S2.

First, the first layer data S1 is inputted to known bit inserting section 910. Known bit inserting section 910 inserts one or more known bits to the first layer data S1. A known bit refers to a bit that both the encoder and decoder know whether the bit is “1” or “0.” Known bit inserting section 910 outputs the first layer data S1 in which known bits are inserted, to first layer encoder 921 and second layer encoder 922.

First layer encoder 921 generates the first layer parity P1 from the first layer data S1 in which known bits are inserted, based on the submatrix H1. Further, second layer encoder 922 generates the second layer parity P2 from the first layer data S1 in which known bits are inserted and the second layer data S2, based on the submatrix H2. By so doing, the encoder according to the present embodiment changes one or more bits of the first layer data S1 to known bits, and transmit the first layer data S1.

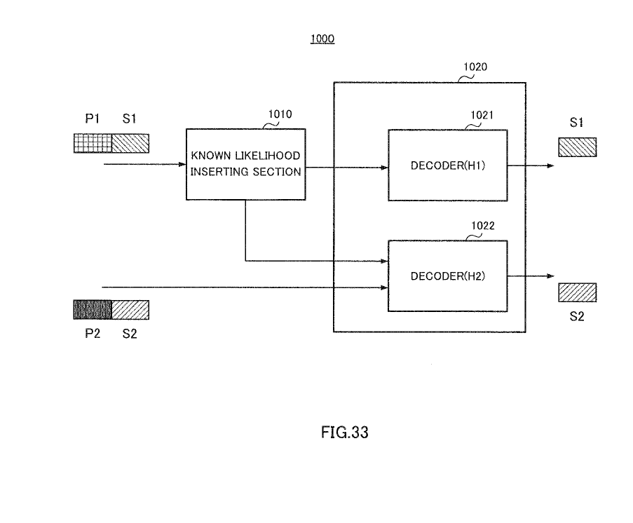

FIG. 33 shows the configuration of the decoder according to the present embodiment. Decoder 1000 in FIG. 33 is constituted by known likelihood inserting section 1010 and decoder (H) 1020. Further, decoder (H) 1020 can employ the same configuration as the decoder explained in Embodiment 1. A case will be explained below as an example where decoder (H) 1020 employs the same configuration as decoder (H) 700A shown in FIG. 26 and is constituted by decoder (H1) 1021 and decoder (H2) 1022.

Out of reception likelihoods of the first layer data S1, known likelihood inserting section 1010 inserts known likelihoods in positions in which known bits are inserted. For example, when log likelihood ratios are used as the reception likelihoods, the symbols of known likelihoods are changed to positive or negative signs corresponding to inserted known bits and the absolute values of the known likelihoods are made much greater absolute values compared to other reception likelihoods. The maximum value that can be processed by decoder (H) 1020 may be made the absolute values of the known likelihoods.

Known likelihood inserting section 1010 outputs the reception likelihoods of the first layer data S1, in which known likelihoods are inserted, and reception likelihoods of the first layer parity P1, to decoder (H1) 1021.

In decoder (H) 1020, decoder (H1) 1021 decodes the first layer data S1 using the reception likelihoods of the first layer data S1, in which known likelihoods are inserted, and reception likelihoods of the first layer parity P1, and outputs the decoding result.

Decoder (H2) 1022 decodes the second layer data S2 using the reception likelihoods of the first layer data S1, in which known likelihoods are inserted, reception likelihoods of the second layer data S2 and reception likelihoods of the second layer parity P2, and outputs the decoding result.

In decoder (H2) 1022, the known likelihoods inserted in reception likelihoods of the first layer data S1 are much great compared to reception likelihoods of other bits and, consequently, play a role of increasing BP decoding performance. Therefore, when the received quality of the first layer data S1 is poor and the reception likelihoods are low, the rate of the first layer data S1 included in the codeword of the second layer data S2 decreases by inserting known likelihoods, so that, by using the reception likelihoods of the first layer data S1 of poor quality, it is possible to prevent the deterioration in performance of decoding the second layer data S2. That is, by inserting known bits, it is possible to prevent influences of noise and interference from spreading from the first layer data S1 to the second layer data S2.

Further, known bits are inserted in the first layer data S1 and, therefore, the amount of data that can be transmitted by the first layer data S2 decreases. However, it is possible to provide an advantage of improving the received quality of the first layer data S1 by inserting known bits, so that it is possible to increase the probability of correct data transmission in an environment where influences of noise and interference are significant.

As described above, according to the present embodiment, encoder 900 has known bit inserting section 910 that inserts known bits in predetermined positions in the first layer data S1. By this means, received quality of the first layer data S1 increases, so that it is possible to increase the probability of correct data transmission in an environment where influences of noise and interference are significant.

Further, the positions to insert known bits in the first layer data S1 can be determined according to the following criterion. The weights of columns (column weights) corresponding to the first layer data S1 in the matrix Hs2 in the submatrix 112, are p1 to pn. Here, n is the data length of the first layer data S1. At this time, a column of a greater column weight spreads greater influences of received quality of the first layer data S1 to the second layer data S2, so that it is possible to prevent deterioration in the received quality of the second layer data S2 in a more reliable manner by preferentially inserting known bits from the column of the greatest weight.

When the number of known bits to insert is K, known bit inserting section 910 inserts known bits in positions in the first layer data S1 corresponding to the K column where the column weights p1 to pn of the matrix Hs2 are great.

In this way, known bit inserting section 910 inserts known bits sequentially from a column that includes more 1's included in a row in the submatrix H2 that is used to find the second layer parity P2, that is, inserts known bits preferentially from the column of the greatest column weight, among columns corresponding to the first layer data S1 in the parity check matrix H, so that it is possible to improve the first received quality that spreads greater influences to the second layer data S2 and, consequently, it is possible to prevent deterioration in the received quality of the second layer data S2.

Further, when the number of known bits to insert is K, known likelihood inserting section 1010 of decoder 1000 only needs to insert known likelihoods in positions in the first layer data S1 corresponding to the K column where the column weights p1 to pn in the matrix Hs2 are great.

### Embodiment 7

An encoder will be explained with the present embodiment that, to insert known bits in the first layer data S1 as explained in Embodiment 6, determines the number of known bits to insert based on received quality fed back from the decoding side (i.e. receiving side).

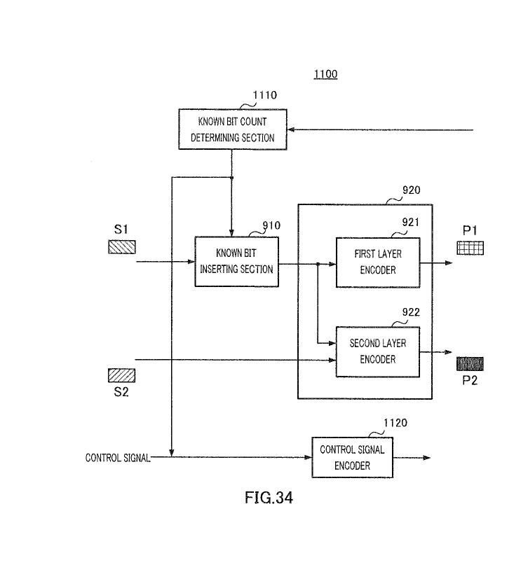

FIG. 34 shows the configuration of the encoder according to the present embodiment. Compared to encoder 900 in FIG. 31, encoder 1100 in FIG. 34 employs a configuration with additions of known bit count determining section 1110 and control signal encoder 1120.

Known bit count determining section 1110 determines the number of known bits to insert in the first layer data S1, based on received quality information fed back from the decoding side (i.e. receiving side) of the communicating party. The policy to determine the number of known bits is that, when received quality information shows that received quality is good, the number of known bits is decreased, and, when received quality information shows that received quality is poor, the number of known bits is increased.

Known bit count determining section 1110 outputs the determined number of known bits to known bit inserting section 910 and control signal encoder 1120. Known bit inserting section 910 inserts in the first layer data S1 a number of known bits outputted from known bit count determining section 1110.

Further, the positions to insert known bits in the first layer data S1 can be determined according to the following criterion. The column weights corresponding to the first layer data S1 in the matrix Hs2 in the submatrix H2, are p1 to pn. Here, n is the data length of the first layer data S1. At this time, a column of a greater column weight spreads greater influences of received quality of the first layer data S1 to the second layer data S2, so that it is possible to prevent deterioration in the received quality of the second layer data S2 in a more reliable manner by preferentially inserting known bits from the column of the greatest weight.

When the number of known bits to insert is K, known bit inserting section 910 inserts known bits in positions in the first layer data S1 corresponding to the K column where the column weights p1 to pn of the matrix Hs2 are great.

Control signal encoder 1120 encodes a control signal including information about the number of known bits, and reports the encoded control signal to the decoding side (i.e. receiving side).

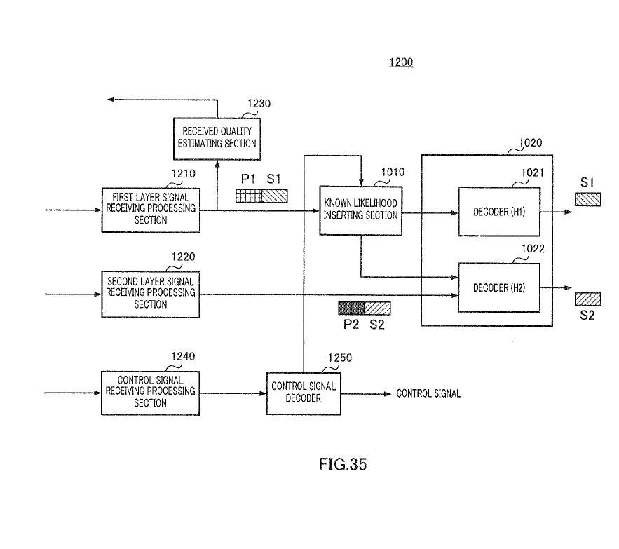

FIG. 35 shows the configuration of the decoder according to the present embodiment. Compared to decoder 1000 in FIG. 33, decoder 1200 in FIG. 35 employs a configuration with additions of first layer signal receiving processing section 1210, second layer signal receiving processing section 1220, received quality estimating section 1230, control signal receiving processing section 1240 and control signal decoder 1250.

First layer signal receiving processing section 1210 calculates the reception likelihoods of the first layer data S1 and first layer parity P1 from the first layer signal received through a communication channel, and outputs these reception likelihoods to received quality estimating section 1230 and known likelihood inserting section 1010.

Second layer signal receiving processing section 1220 calculates the reception likelihoods of the second layer data S2 and second layer parity P2 from the second layer signal received through a communication channel, and outputs these reception likelihoods to decoder (H2) 1022.

Control signal receiving processing section 1240 calculates reception likelihoods of a control signal received through communication channel, and outputs these reception likelihoods to control signal decoder 1250. Further, any wireless communication channels and wired communication channels such as power line and optical fibers can be used as communication channels.

Control signal decoder 1250 decodes a control signal, extracts the number of known bits included in the control signal and outputs the extracted number of known bits, to known likelihood inserting section 1010.

When the number of known bits to insert is K, known likelihood inserting section 1010 inserts known likelihoods in positions in the first layer data S1 corresponding to the K column where the column weights p1 to pn of the matrix Hs2 are great.

Received quality estimating section 1230 estimates the received quality of the first layer signal from the reception likelihoods of the first layer data S1 and first layer parity P1. Received quality estimating section 1230 reports the estimated received quality to the encoding side (i.e. transmitting side) using a feedback communication channel.

As described above, according to the present embodiment, encoder 1100 has known bit count determining section 1110 that determines the number of known bits to insert in the first layer data S1 based on received quality that is fed back from the communicating party of the decoding side (i.e. receiving side). By so doing, when received quality is good and spreading of the influences of noise and interference from the first layer data S1 to the second layer data S2 is not a problem, it is possible to prevent decrease in the amount of the first layer data S1 due to insertion of known bits by decreasing the number of known bits, and, when received quality is extremely poor, it is possible to enhance the advantage of preventing the influences of noise and interference from spreading from the first layer data S1 to the second layer data S2 by increasing the number of known bits.

### Embodiment 8

Cases have been explained with Embodiments 1 to 7 as examples where bit error is corrected. A case will be explained with the present embodiment as an example where the present invention is applied to erasure correction of source symbols, source blocks or packets.

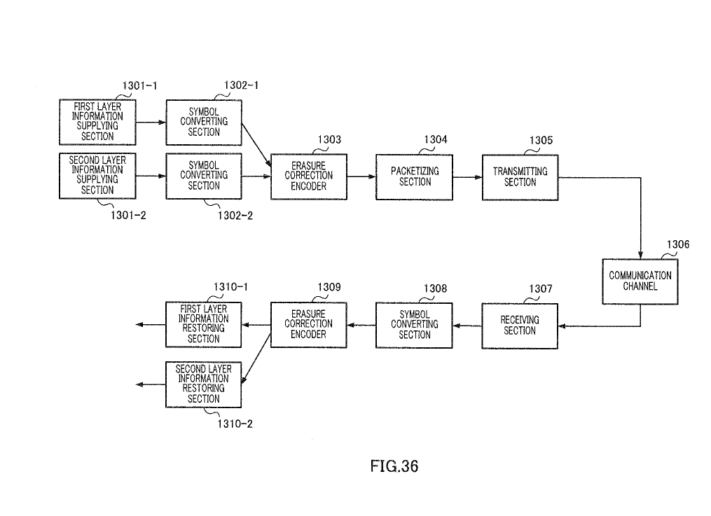

FIG. 36 shows the overall configuration of the communication system according to the present embodiment. The communication system shown in FIG. 36 transmits and receives first layer information S1 and second layer information S2.

In FIG. 36, the communication system is constituted by first layer information supplying section 1301-1, second layer information supplying section 1301-2, symbol converting sections 1302-1 and 1302-2, erasure correction encoder 1303, packetizing section 1304, transmitting section 1305, communication channel 1306, receiving section 1307, symbol converting section 1308, erasure correction decoder 1309, first layer information restoring section 1310-1 and second layer information restoring section 1310-2.

First layer information supplying section 1301-1 and second layer information supplying section 1301-2 hold the first layer information S1 and second layer information S2, and outputs these items of information to symbol converting sections 1302-1 and 1302-2.

Symbol converting section 1302-1 clips the first layer information S1 in units that are referred to as “source blocks” determined in advance. Further, symbol converting section 1302-1 divides a source block that is clipped, into source symbols of a predetermined size. Symbol converting section 1302-1 outputs the source symbols to erasure correction encoder 1303. By the way, the entire first layer information S1 may be regarded as one source block without clipping the first layer information S1.

Similarly, symbol converting section 1302-2 divides the second layer information S2 into source symbols of a predetermined size, and outputs the source symbols to erasure correction encoder 1303. Further, similar to the first layer information S2, the entire second layer information S2 may be regarded as one source symbol.

Erasure correction encoder 1303 performs erasure correction encoding processing using the source symbols of the first layer information S1 and the source symbols of the second layer information S2, generates parity symbols and outputs the generated parity symbols to packetizing section 1304. Further, erasure correction encoder 1303 generates the first layer parity symbol P1 for the first layer information S1, from the source symbols of the first layer information S1, and generates the second layer parity symbol P2 for the second layer information S2, from the source symbols of the first layer information S1 and the source symbols of the second layer information S2.

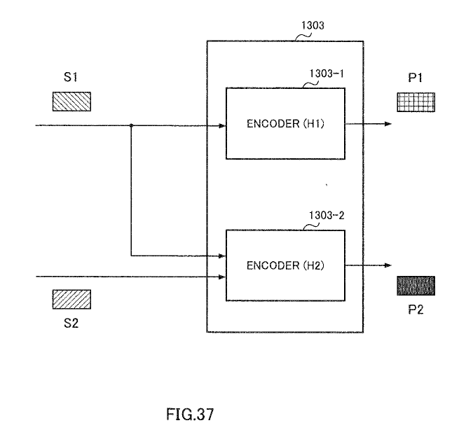

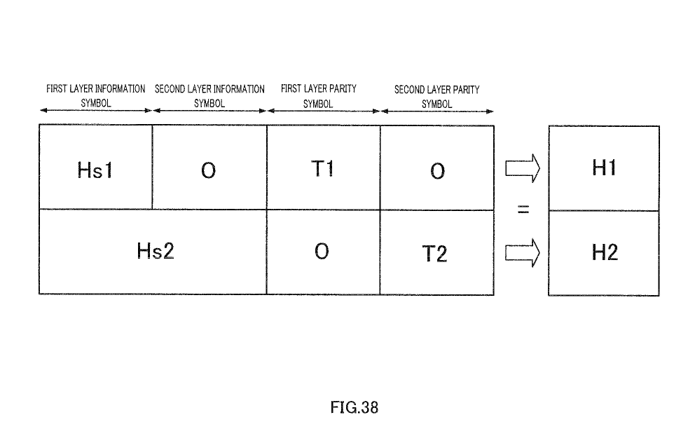

FIG. 37 shows a configuration example of erasure correction encoder 1303. Erasure correction encoder 1303 performs erasure correction encoding processing according to the parity check matrix H shown in FIG. 38. Encoder (H1) 1303-1 encodes the first layer information symbol S1 according to the submatrix H1 of the parity check matrix H, and generates the first layer parity symbol P1. Further, encoder (H2) 1303-2 encodes the first layer information symbol S1 and second layer information symbol S2 according to the submatrix H2 of the parity check matrix H, and generates the second layer parity symbol P2.

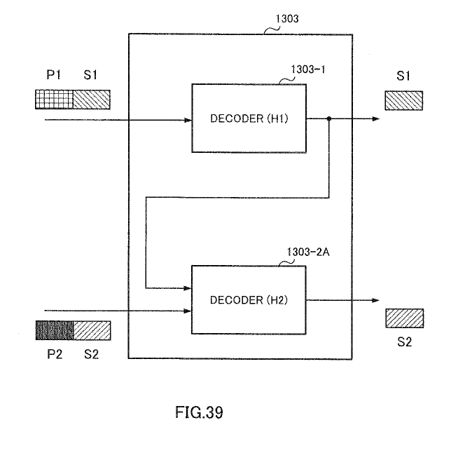

Further, as to the configuration of erasure correction encoder 1303 and the erasure correction coding method, other configurations and encoding methods explained in the above embodiments may be used. While coding processing is performed in bit units with the above embodiments, the present embodiment differs from the above embodiments in performing coding processing in symbol units. However, encoding processing is performed only in different processing units, so that coding processing only needs to be performed in symbol units instead of in bit units. Accordingly, erasure correction encoder 1303 may employ the configuration shown in FIG. 39.

Erasure correction encoder 1303 outputs the first layer information symbol S1, first layer parity symbol P1, second layer information symbol S2 and second layer parity symbol P2, to packetizing section 1304.

Packetizing section 1304 generates packets from the first layer information symbol S1, first layer parity symbol P1, second layer information symbol S2 and second layer parity symbol P2, and outputs the generated packets to transmitting section 1305.

Transmitting section 1305 transmits the packets to communication channel 1306.

Receiving section 1307 receives the packets that have arrived through communication channel 1306. At this time, there are cases depending on the condition of the communication channel where packets that are transmitted cannot be detected in receiving section 1307 and packet loss occurs. Receiving section 1307 outputs packets that are received correctly, to symbol converting section 1308, and outputs ID's of packets that have been lost, to symbol converting section 1308.

Symbol converting section 1308 converts the received packets into symbols, and outputs the resulting symbols to erasure correction decoder 1309.

Erasure correction decoder 1309 performs erasure correction decoding processing of symbols that have not been lost, and restores symbols that have been lost. To be more specific, erasure correction decoder 1309 restores the lost first layer information symbol S1 from the received first layer information symbol S1 and first layer parity symbol P1. Further, erasure correction decoder 1309 restores the lost second layer information symbol S2 from the received first layer information symbol S1, second layer information symbol S2 and second layer parity symbol P2. The method of erasure correction decoding is not limited in particular.

Erasure correction decoder 1309 outputs the first layer information symbol S1 and second layer information symbol S2 after erasure correction decoding, to first layer information restoring section 1310-1 and second layer information restoring section 1310-2, respectively.

First layer information restoring section 1310-1 and second layer information restoring section 1310-2 restore source blocks from source symbols. The first layer information and second layer information are restored in this way.

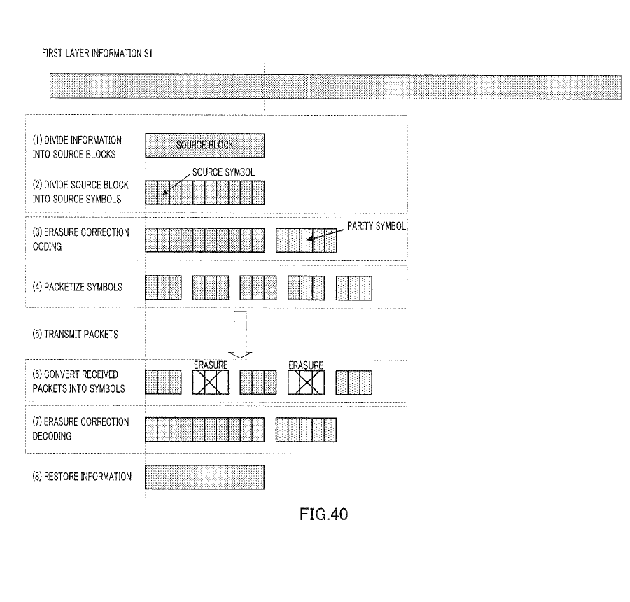

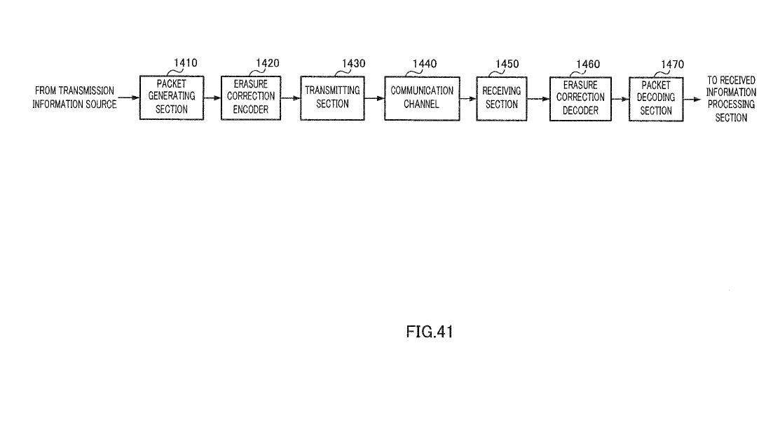

The flowchart of transmitting and receiving signals in the communication system constituted as described above, will be explained using FIG. 40 as an example. (1) Symbol converting sections 1302-1 and 1302-2 clip the first layer information S1 in units that are referred to as “source blocks” determined in advance. (2) Symbol converting sections 1302-1 and 1302-2 divide source blocks into source symbols of a predetermined size. (3) Erasure correction encoder 1303 performs erasure correction encoding processing in symbol units using the source symbols of the first layer information S1 and the source symbols of the second layer information S2, and generates the first layer parity symbol P1 and second layer parity symbol P2. (4) Packetizing section 1304 generates transmission packets from the first layer information symbol S1, first layer parity symbol P1, second layer information symbol S2 and second layer parity symbol P2. Further, although, with an example of FIG. 40, packetizing section 1304 packetizes symbols after erasure correction coding without reordering the symbols, packetizing may be performed by reordering symbols. (5) Transmitting section 1305 transmits transmission packets to receiving section 1307 through communication channel 1306. (6) Symbol converting section 1308 converts the received packets into symbols, and outputs the resulting symbols to erasure correction decoder 1309. FIG. 40 shows an example where the second and fourth packets are lost. (7) Erasure correction decoder 1309 performs erasure correction decoding processing of symbols that are not lost, and restores symbols that have been lost. (8) First layer information restoring section 1310-1 and second layer information restoring section 1310-2 restore source blocks from source symbols.

As described above, according to the present embodiment, symbol converting sections 1302-1 and 1302-2 convert the first layer information S1 and second layer information S2 into source symbols of the first layer information S1 and source symbols of the second layer information S2, and erasure correction encoder 1303 performs erasure correction coding processing in symbol units using the source symbols of the first layer information S1 and the source symbols of the second layer information S2, and generates the first layer parity symbol P1 and second layer parity symbol P2. In this way, the first layer information S1 and second layer information S2 are converted into symbols in symbol converting sections 1302-1 and 1302-2, and then are subjected to erasure correction coding in symbol units in erasure correction encoder 1303. By so doing, when processing is performed in symbol units, information jointing a plurality of layers can be encoded and decoded, so that it is possible to improve the reliability of transmission of upper layer information.

Further, although a case has been explained so far where symbol converting sections 1302-1 and 1302-2 divide source blocks into source symbols and erasure correction encoder 1303 performs erasure correction coding processing in symbol units, erasure correction encoder 1303 may perform erasure correction coding processing in source block units without dividing source blocks into source symbols in symbol converting sections 1302-1 and 1302-2.

Further, the configuration may also be possible where erasure correction encoder 1303 is provided subsequent to packetizing section 1304, packetizing section 1304 packetizes the first layer information S1 and second layer information S2 and then erasure correction encoder 1303 performs erasure correction coding processing in packet units.

That is, the first layer information S1 is a sequence provided in the first information block (e.g. source symbol, source block and packet) and the second layer information S2 is a sequence provided in the second information block (e.g. source symbol, source block and packet), and erasure correction encoder 1303 generates the first and second parity blocks in the first information block units and second information block units.

Further, in the communication system according to the present embodiment, when known packets are inserted in the first layer information as explained in Embodiment 6, it is possible to control how many first layer information and second layer information are jointed according to the amount of insertion of known packets.

### Embodiment 9

A communication system will be explained with the present embodiment where, in a communication system adopting error correction, packets (source symbols or source blocks) forming the minimum stopping set in an LDPC code parity check matrix are changed to known packets (known symbols or known blocks) explained in Embodiment 6, to suppress deterioration in erasure correction performance due to the minimum stopping set, joint first layer information and second layer information, and improve the error characteristics.

The communication system that performs erasure correction in packet units will be explained as an example below.

First, the communication system that performs packet erasure correction and that changes packets forming a minimum stopping set to known packets, will be explained.

FIG. 41 shows an overall configuration of the communication system according to the present embodiment. In FIG. 41, the communication system is constituted by packet generating section 1410, erasure correction encoder 1420, transmitting section 1430, communication channel 1440, receiving section 1450, erasure correction decoder 1460 and packet decoding section 1470. In the same figure, packet generating section 1410, erasure correction encoder 1420 and transmitting section 1430 are on the encoding side, and receiving section 1450, erasure correction decoder 1460 and packet decoding section 1470 are on the decoding side.

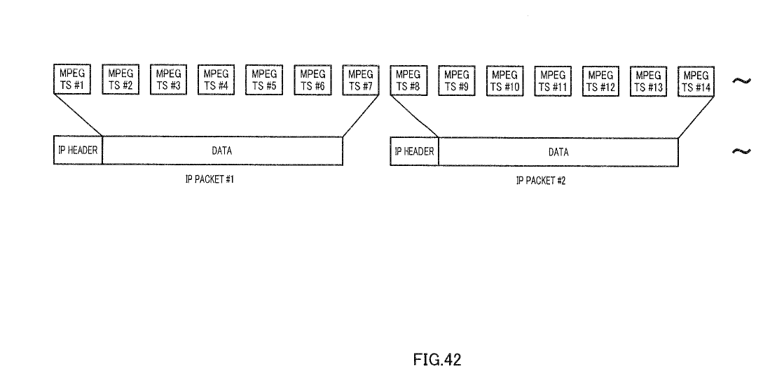

Packet generating section 1410 adds a header to transmission information outputted from the transmission information source, and converts this information into an information packet. For example, as shown in FIG. 42, to convert TS's (Transport Streams) of MPEG (Moving Picture Expert Group) given as transmission information, into an IP packet, packet generating section 1410 binds seven MPEG-TS's and adds an IP header to the head of the seven MPEG-TS's, to generate an IP packet. Packet generating section 1410 outputs the generated information packet to erasure correction encoder 1420.

Erasure correction encoder 1420 performs erasure correction coding processing with respect to the information packet outputted from packet generating section 1410. To be more specific, as erasure correction coding processing, erasure correction encoder 1420 adds, upon encoding, a redundant packet every other determined number of information packets. Erasure correction encoder 1420 outputs the information packet and redundant packet to transmitting section 1430. Hereinafter, an information packet and redundant packet will be referred to as a “transmission packet.”

Depending on a medium that is used as the communication channel, transmitting section 1430 converts the transmission packet outputted from erasure correction encoder 1420, into a format that can be transmitted through the communication channel, and transmits the transmission packet to communication channel 1440.

Communication channel 1440 refers to the route through which a signal transmitted from transmitting section 1430 passes until it is received by receiving section 1450. As communication channels, Ethernet (registered trademark), power line, metal cables, optical fibers, radio, light (e.g. visible light or infrared light) and combinations of these may be used.

Receiving section 1450 receives a signal that arrives from transmitting section 1430 through communication channel 1440, and converts the signal into the transmission packet format again. Hereinafter, these transmission packets will be referred to as “received packets.” Receiving section 1450 outputs the received packets to erasure correction decoder 1460.

When there are packets that have been lost among the received packets, erasure correction decoder 1460 performs restoring processing of lost packets utilizing redundant packets added by erasure correction encoder 1420 of the encoding side. Erasure correction decoder 1460 outputs only the packets corresponding to information packets out of received packets subjected to restoring processing, to packet decoding section 1470. By contrast with this, when there are no packets that have been lost among received packets, erasure correction decoder 1460 outputs only the packets corresponding to information packets among the received packets without performing decoding processing.

Packet decoding section 1470 converts packetized transmission information into a format that can be decrypted in the received information processing section (not shown), and transmits the packetized transmission information to the received information processing section. With the example of FIG. 42, the seven MPEG-TS's are extracted from data of the IP packet and are outputted to the received information processing section.

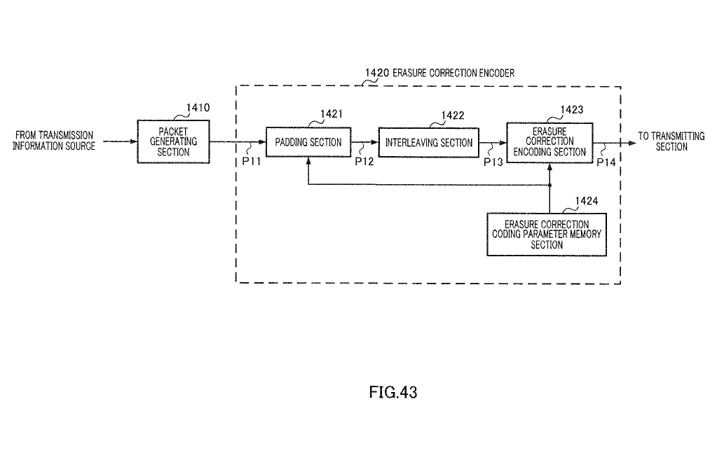

FIG. 43 shows the configuration of main parts of erasure correction encoder 1420. Erasure correction encoder 1420 uses a low density parity check (LDPC) code as an erasure correction code. A case will be explained below as an example where erasure correction encoder 1420 performs erasure correction coding in J information packet units. Packet generating section 1410 outputs the J generated information packets to erasure correction encoder 1420 at a time. Further, the number of information packets J is determined based on the total amount of information to transmit and the number of packets to transmit per time.

Erasure correction encoder 1420 is constituted by padding section 1421, interleaving section 1422, erasure correction encoding section 1423 and erasure correction coding parameter memory section 1424.

Erasure correction coding parameter memory section 1424 stores LDPC code parameters used to perform erasure correction coding. To be more specific, the parity check matrix H, encoded packet length N, organizing packet length K, redundant packet length M and padding packet length P are stored as LDPC code parameters.

Padding section 1421 adds a padding packet that is known by both the encoding side and decoding side, to the rear portion of the J information packets outputted from packet generating section 1410, and generates an organizing packet sequence formed with K packets. Padding section 1421 adds a padding packet based on the padding packet length P held in erasure correction coding parameter memory section 1424, and outputs the organizing packet sequence to interleaving section 1422.

Interleaving section 1422 performs interleaving processing of reordering packets of the organizing packet sequence. Interleaving section 1422 outputs the interleaved organizing packet sequence (hereinafter, referred to as “interleaved packet sequence), to erasure correction encoding section 1423. Further, interleaving processing will be described later.

Erasure correction encoding section 1423 performs LDPC coding processing of the interleaved packet sequence based on the parity check matrix H held in erasure correction coding parameter memory section 1424, and generates a redundant packet sequence. Further, erasure correction encoding section 1423 adds the generated redundant packet sequence to the rear portion of the interleaved packet sequence, and outputs the encoded packet sequence after the redundant packet is added, to transmitting section 1430.

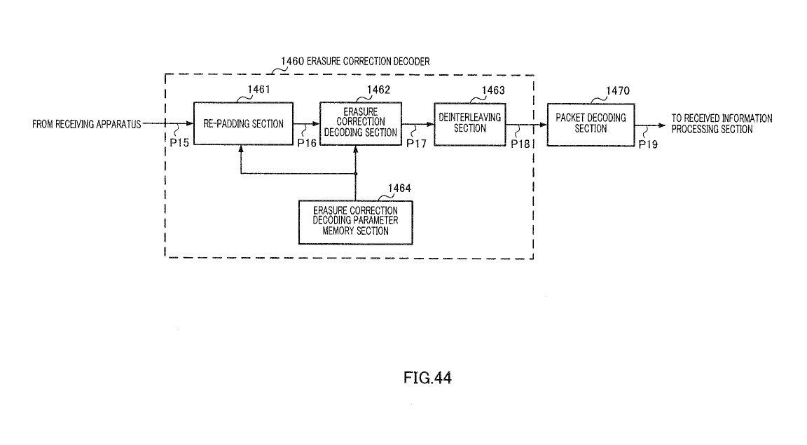

FIG. 44 shows the configuration of main parts of erasure correction decoder 1460. Erasure correction decoder 1460 is constituted by re-padding section 1461, erasure correction decoder 1462, deinterleaving section 1463 and erasure correction decoding parameter memory section 1464.

Erasure correction decoding parameter memory section 1464 stores LDPC code parameters used to perform erasure correction coding/decoding.

When packet loss occurs in the received packet sequence and when the padding packet is lost, re-padding section 1461 inserts a padding packet again in a position in which the packet loss has occurred. Re-padding section 1461 outputs the packet sequence that is re-padded (i.e. re-padded packet sequence) to erasure correction decoding section 1462.

Erasure correction decoding section 1462 performs erasure correction decoding processing of the re-padded packet sequence based on the parity check matrix H, extracts only packets corresponding to the organizing packet sequence from the decoding result and outputs the extracted organizing packet sequence after erasure correction decoding, to deinterleaving section 1463.

Deinterleaving section 1463 performs inverse reordering processing (i.e. deinterleaving processing) of interleaving processing performed on the encoding side, with respect to the organizing packet sequence after erasure correction decoding. Deinterleaving section 1463 outputs only the packets corresponding to the information packet sequence in the organizing packet sequence that is subjected to deinterleaving processing, to packet decoding section 1470.

The operations of erasure correction encoder 1420 and erasure correction decoder 1460 in the communication system constituted as described above, will be mainly explained below. Further, a case will be explained below as an example where three information packets (J=3) are outputted from packet generating section 1410. Furthermore, a case will be explained as an example where erasure correction coding/decoding is performed using the above described matrix represented by equation 12 as the parity check matrix H that defines an LDPC code used in loss error correction coding. The parity check matrix H of equation 12 is an example of a case where the encoded packet length is N=10, the organizing packet length is K=5 and the redundant packet length is M=5.

$$\begin{matrix}( Equation 12 ) & \\ H = ( \begin{matrix}1 & 1 & 0 & 1 & 1 & 1 & 1 & 0 & 0 & 0 \\ 1 & 1 & 0 & 0 & 1 & 0 & 0 & 1 & 1 & 1 \\ 1 & 0 & 1 & 0 & 1 & 0 & 1 & 0 & 1 & 1 \\ 0 & 1 & 1 & 1 & 0 & 1 & 0 & 1 & 1 & 0 \\ 0 & 0 & 1 & 1 & 0 & 1 & 1 & 1 & 0 & 1\end{matrix} ) & [ 12 ]\end{matrix}$$

(The Operation of the Erasure Correction Encoder)

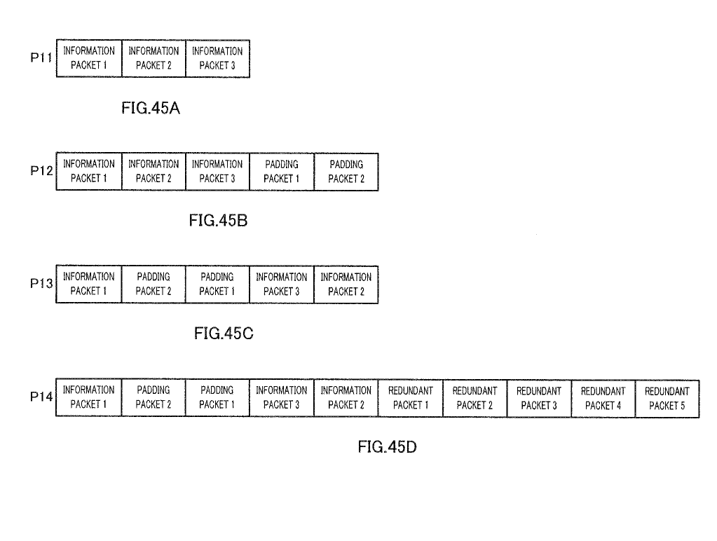

FIG. 45 shows input and output packet sequences of each section of erasure correction encoder 1420. Further, the same reference numerals as the corresponding packet sequences of FIG. 45 will be assigned in FIG. 43.

FIG. 45A shows the information packet sequence P11 outputted from packet generating section 1410. The information packet sequence P11 is formed with three information packets.

Padding section 1421 adds a padding packet sequence formed with two (=P=K−J) padding packets, to the rear portion of the information packet sequence P11 outputted from packet generating section 1410, and generates the organizing packet sequence P12 formed with five packets (see FIG. 45B).

Interleaving section 1422 performs interleaving processing of the organizing packet sequence P12. Practically, interleaving section 1422 performs interleaving by means of the following processings.

(Interleaving Processing)

(1) All minimum stopping sets included in the parity check matrix H are extracted. (2) How many minimum stopping sets in all combinations of minimum stopping sets include each variable node corresponding to the organizing packet sequence is checked. (3) Each variable node corresponding to the organizing packet sequence is reordered in order from the variable node included in the greatest number of minimum stopping sets. Hereinafter, the reordering result will be referred to as the “variable node list.” (4) The packet of the variable node corresponding to the first place in the variable node list is replaced with the packet at the tail of the organizing packet sequence P12, that is, a redundant packet. (5) Next, the packet of the variable node corresponding to the second place in the variable node list is replaced with the second packet from the tail of the organizing packet sequence, that is, a redundant packet. (6) Therefore, a packet corresponding to a variable node corresponding to a higher place in the variable node list is sequentially replaced with a redundant packet of the organizing packet sequence to perform interleaving processing.

In this way, to perform interleaving processing, interleaving section 1422 performs processing of replacing the packet positioned in the rear portion of the organizing packet sequence P12 with a packet positioned to correspond to one of variable nodes forming minimum stopping sets in the parity check matrix H that is used in LDPC coding. By replacing the packet positioned in the rear portion of the organizing packet sequence P12 with the packet positioned to correspond to one of variable nodes forming minimum stopping sets in the parity check matrix H that is used in LDPC coding, interleaving section 1422 assigns padding packets to the positions corresponding to variable nodes forming minimum stopping sets.

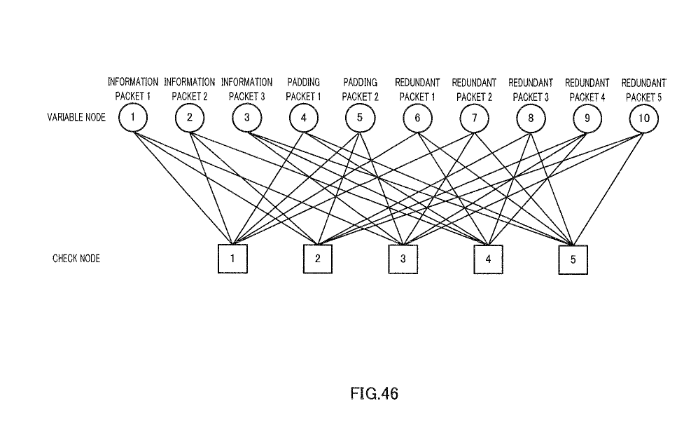

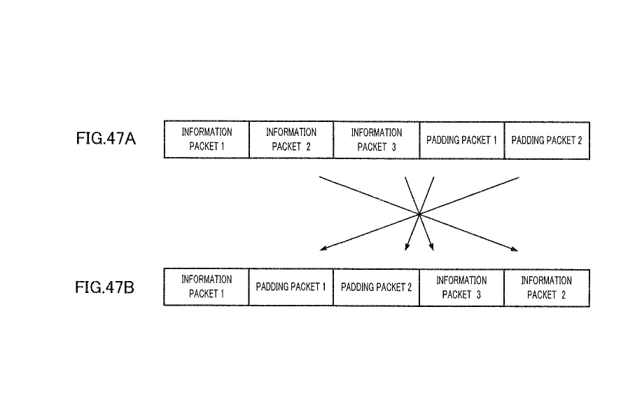

When above steps (1) to (6) are performed, a redundant packet is preferentially assigned to the position corresponding to a variable node provided in order from a variable node included in the greatest number of minimum stopping sets. Interleaving processing will be explained supplementarily further using FIG. 46.

FIG. 46 shows a Tanner graph matching the parity check matrix H of equation 12. In FIG. 46, variable nodes in the upper part correspond to each column of the parity check matrix H of equation 12 and check nodes in the lower part correspond to each row of the parity check matrix H. When the element is 1 in the i-th row and the j-th column of the parity check matrix H, the j-th variable node and i-th check node is connected with a line.

Further, packets assigned to variable nodes when interleaving processing is not performed prior to erasure correction coding processing, are also shown above the variable nodes in FIG. 46. As shown in FIG. 46, the information packets 1 to 3 correspond to the variable nodes 1 to 3, the padding packets 1 and 2 correspond to the variable nodes 4 and 5 and the redundant packets 1 to 5 resulting from erasure correction coding processing correspond to the variable nodes 6 to 10.

The minimum stopping set size of the parity check matrix H obtained by equation 12 is three, and there are seven combinations of variable nodes, as shown by equation 13-1 to equation 13-7 (where the numbers in [ ] represent indices of variable nodes).

[13]

SS1=[1,2,9] (Equation 13-1)

SS2=[2,4,8] (Equation 13-2)

SS3=[2,5,9] (Equation 13-3)

SS4=[2,6,8] (Equation 13-4)

SS5=[3,4,7] (Equation 13-5)

SS6=[3,6,7] (Equation 13-6)

SS7=[3,8,9] (Equation 13-7)

The variable node included in the greatest number of minimum stopping sets out of the above seven minimum stopping sets, is the variable node 2 (included in four patterns out of the seven patterns). Further, the variable node included in the second greatest number of minimum stopping sets, is the variable node 3 (included in three patterns out of the seven patterns).

Interleaving section 1422 replaces (i.e. interleaves) the packet (padding packet 2) at the tail of the organizing packet sequence P12, with the information packet 2 positioned to correspond to the variable node 2. Further, interleaving section 1422 replaces the information packet 3 positioned to correspond to the variable node 3, with the second packet (padding packet 1) from the tail of the organizing packet sequence P12. FIG. 47 shows the interleaving processing pattern in this case. FIG. 47A shows the order of packets before interleaving and FIG. 47B shows the order of packets after interleaving.

In this way, interleaving section 1422 performs processing of replacing packets in the rear portion of the organizing packet sequence P12, with the packets that are assigned to part of variable nodes of stopping sets. That is, interleaving section 1422 replaces information packets positioned to correspond to variable nodes forming minimum stopping sets in the parity check matrix H, with padding packets which are known packets. As a result, the interleaved packet sequence P13 shown in FIG. 45C is acquired.

By so doing, the padding packets 2 and 1 are arranged in the positions of the variable node 2 included in the greatest number of minimum stopping sets and the variable node 3 included in the second greatest number of minimum stopping sets. The padding packets 2 and 1 are known packets, so that, even when the padding packets 2 and 1 positioned to correspond to the variable node 2 and 3 are lost in communication channel 1440, re-padding section 1461 of erasure correction decoder 1460 of the decoding side can re-pad the padding packets 2 and 1 that have been lost. Consequently, even when packets positioned to correspond to other variable nodes as minimum stopping sets including the variable nodes 2 and 3 are lost, there is a possibility that erasure correction decoding section 1462 can perform erasure correction decoding.

By contrast with this, when the information packets 2 and 3 positioned to correspond to the variable nodes 2 and 3 are lost because interleaving processing is not performed, the information packets 2 and 3 are not known and, therefore, it is difficult for re-padding section 1461 to perform re-padding. Further, when packets positioned to correspond to other variable nodes as minimum stopping sets including the variable nodes 2 and 3 are lost, there is a higher possibility that erasure correction decoding section 1462 fails to perform erasure correction decoding processing.

Erasure correction encoding section 1423 generates the redundant packets 1 to 5 based on the parity check matrix H held in erasure correction coding parameter memory section 1424 and adds the redundant packets 1 to 5 to the interleaved packet sequence P13 to generate the encoded packet sequence P14 configured with the N packets shown in FIG. 45D.

In this way, interleaving section 1422 assigns a padding packet preferentially to a position corresponding to the variable node included in the greatest number of minimum stopping sets in the parity check matrix H. By so doing, even when a packet positioned to correspond to a variable node that influences erasure correction significantly is lost, re-padding section 1461 of erasure correction decoder 1460 of the decoding side can perform re-padding, so that it is possible to increase the possibility of erasure correction decoding.

(The Operation of the Erasure Correction Decoder)

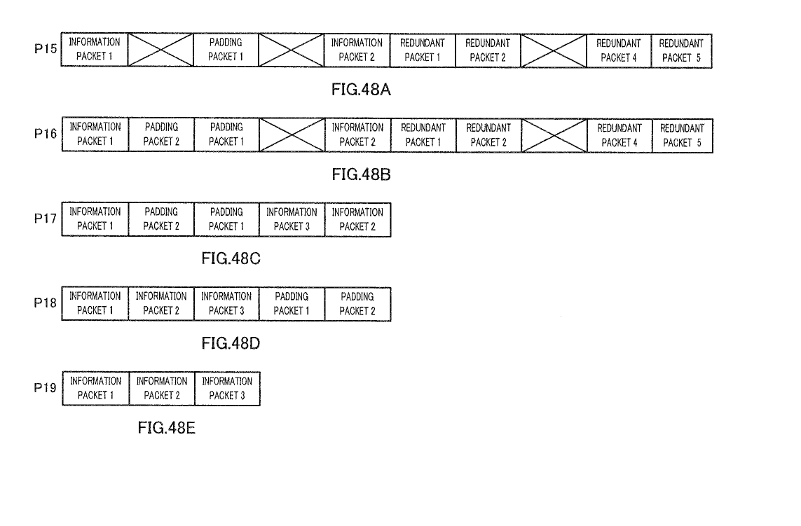

Next, the operation of erasure correction decoder 1460 will be explained. FIG. 48 shows packet sequences inputted in and outputted from each section of erasure correction decoder 1460. Further, the same reference numerals as the corresponding packet sequences in FIG. 48 will be assigned in FIG. 44.

FIG. 48A shows the received packet sequence P15 outputted from receiving section 1450. In FIG. 48A, three packets to which × symbols are assigned represent packets that have been lost in communication channel 1440. FIG. 48A shows an example of a case where the second, fourth and eighth packets have been lost. Variable nodes corresponding to three lost packets are the variable nodes 2, 4 and 8, and the combination of these variable nodes [2, 4, 8] matches the minimum stopping set SS2 shown in equation 14. Further, one of the lost packets (the second packet) is the padding packet 2 that is padded on the encoding side.

Re-padding section 1461 determines the position to which the padding packet is inserted on the encoding side, based on the number of padding packets P(2) held in erasure correction decoding parameter memory section 1464 and a pattern of deinterleaving performed in deinterleaving section 1463. Further, re-padding section 1461 decides whether or not padding packets are included in the lost packets and, when padding packets are included in the lost packets, re-padding section 1461 inserts padding packets again to the positions of the lost packets. Here, the packet in the second position from the head of the packet sequence is the padding packet 2 and, consequently, re-padding section 1461 inserts the padding packet 2 to the second packet position. As a result, the packet sequence P16 shown in FIG. 48B is acquired. Further, when padding packets are not included in the lost packets, re-padding section 1461 outputs the received packet sequence P15 to erasure correction decoding section 1462 as the packet sequence P16 without performing re-padding.

When packet loss occurs in the organizing packet sequence in the packet sequence P16, erasure correction decoding section 1462 performs erasure correction decoding processing based on the parity check matrix H held in erasure correction decoding parameter memory section 1464. An iterative decoding algorithm such as BP (Belief Propagation) may be used for erasure correction decoding processing. After decoding processing is finished, erasure correction decoding section 1462 outputs only the organizing packet sequence P17 to deinterleaving section 1463 as shown in FIG. 48C.

By contrast with this, when packet loss does not occur in the packet sequence P16 or when packet loss occurs only in a redundant packet sequence, erasure correction decoding section 1462 does not perform erasure correction decoding processing and outputs only the organizing packet sequence P17 to deinterleaving section 1463.

Deinterleaving section 1463 performs inverse processing of interleaving processing performed in interleaving section 1422 of the encoding side, with respect to the organizing packet sequence P17, and reorders packets. Referring to the above described example of FIG. 45, deinterleaving section 1463 replaces the padding packet 2 with the information packet 2 and replaces the padding packet 1 with the information packet 3. FIG. 48D shows the deinterleaved organizing packet P18. The order of packets in the organizing packet sequence P18 in FIG. 48D matches the order of packets in the organizing packet sequence P12 before interleaving on the encoding side (see FIG. 45B).

Deinterleaving section 1463 outputs the information packet sequence P19 formed with information packets of the deinterleaved organizing packet sequence P18 shown in FIG. 48E, to packet decoding section 1470.

As described above, interleaving section 1422 of the encoding side assigns padding packets to positions corresponding to variable nodes forming minimum stopping sets. With the example of FIG. 45, interleaving section 1422 assigns a padding packet to the variable node 2. Consequently, even when packets (the second, fourth and eight packets) corresponding to variable nodes as the minimum stopping set S22 are lost in communication channel 1440, the second packet can be restored by means of re-padding, so that it is possible to avoid failure of erasure correction due to SS2, in packet decoding section 1470. Further, with the example of FIG. 46, it is also possible to avoid failure of erasure correction due to other stopping sets (SS1, SS3 and SS4) than SS2 including the variable node 2 by changing the variable node 2 to a known padding packet.

In this way, interleaving section 1422 of the encoding side replaces the redundant packet positioned in the rear portion of the organizing packet sequence P12, with the packet positioned to correspond to one of variable nodes forming minimum stopping sets in the parity check matrix H that is used in LDPC coding, and, consequently, even when packet loss occurs in positions of minimum stopping sets in communication channel 1440, re-padding section 1461 can perform re-padding, so that it is possible to avoid failure of erasure correction due to minimum stopping sets.

As described above, according to the present embodiment, erasure correction encoder 1420 has: padding section 1421 that adds padding packets to the information packet sequence; interleaving section 1422 that replaces padding packets with information packets; and loss coding section 1423 that performs erasure correction coding of the interleaved packet sequence, and interleaving section 1422 replaces padding packets with information packets based on variable nodes forming minimum stopping sets in the parity check matrix that defines the low density parity check code. Further, erasure correction decoder 1460 has: re-padding section 1461 that performs re-padding of the received packet sequence; erasure correction decoding section 1462 that performs erasure correction decoding of the packet sequence after re-padding; and deinterleaving section 1463 that reorders the packet sequence after erasure correction decoding. Consequently, it is possible to reduce the probability of failure of erasure correction due to minimum stopping sets by changing the pattern of replacing information packets with known packets, to a reordering pattern to avoid failure of erasure correction due to minimum stopping sets, based on variable nodes forming minimum stopping sets that are directed to limiting characteristics of correction performance of the LDPC parity check matrix.

In this way, by using the present invention, it is possible to provide an advantage of reducing the probability of failure of correction due to minimum stopping sets which are the first factor that deteriorates the correction performance of erasure correction coding by utilizing adequate interleaving/deinterleaving and padding packets that are conventionally inserted to adjust the number of packets involving erasure correction coding/decoding. That is, it is possible to reduce that probability that packets lost in a communication channel match packets of minimum stopping sets included in the parity check matrix and, consequently, improve erasure correction performance.

In case where interleaving section 1422 performs interleaving by replacing information packets positioned to correspond to variable nodes forming minimum stopping sets, with known packets, even when packet loss occurs in positions of minimum stopping sets, re-padding section 1461 of the decoding side re-pads lost packets, so that it is possible to avoid failure of erasure correction due to minimum stopping sets.

(The Other Example of Interleaving Processing)

Further, interleaving section 1422 according to Embodiment 1 of the present invention may perform interleaving by means of the following processings.

(1) All minimum stopping sets included in the parity check matrix H are extracted. (2) How many minimum stopping sets of all combinations of minimum stopping sets include each variable node corresponding to the organizing packet sequence is checked. (3) Each variable node corresponding to the organizing packet sequence is reordered in order from a variable node included in the greatest number of minimum stopping sets to create a variable node list. (4) The packet of a variable node corresponding to the first place in the variable node list is replaced with the packet at the tail of organizing packet sequence P12, that is, a redundant packet. (5′) Variable nodes included in minimum stopping sets including the variable node corresponding to the first place are removed from the variable node list. The packet of the variable node corresponding to the top in the variable node list after removal is replaced with the second packet from the tail of the organizing packet sequence, that is, replaced with a redundant packet. (6′) Subsequently, the variable nodes included in minimum stopping sets including the variable node corresponding to the top in the variable node list is removed and the packet of the variable node corresponding to the top in the variable node list after removal is replaced with a redundant packet of the organizing packet sequence to perform interleaving processing.

By so doing, a padding packet is arranged in the position of at least one of variable nodes forming minimum stopping sets. By this means, even when the number of packets that are lost in communication channel 1440 is great, the decoding side can re-pad a known packet in a position of at least one of variable nodes forming minimum stopping sets, so that it is possible to prevent failure of erasure correction due to minimum stopping sets.

Further, although a case has been explained so far where the position to add a padding packet in padding section 1421 is the rear portion of an information packet sequence, the present invention is not limited to this and the position to add the padding packet may be at the head or middle of the information packet sequence as long as this position is known between the encoding side and the decoding side. For example, when padding section 1421 adds a padding packet to the head of an information packet sequence, interleaving section 1422 may perform interleaving processing using an interleaving pattern of replacing a packet corresponding to the top in the variable node list, with the packet at the front head of the organizing packet sequence. When padding section 1421 adds a padding packet to the middle of an information packet sequence, interleaving section 1422 sequentially replaces packets in the middle of the information sequence, with packets of variable nodes described in the variable node list.

Further, although a case has been explained with the present embodiment where the parity check matrix H shown in equation 12 is used, the parity check matrix H is not limited to the parity check matrix shown in equation 12 and, even when other check matrices are used, it is possible to provide the same advantage by using the present invention.

In addition, similar to the known bit inserting section of Embodiment 6, padding section 1421 inserts known packets (known symbols or known blocks) and interleaving section 1422 changes packets (symbols or blocks) forming minimum stopping sets in an LDPC code parity check matrix, to known packets (known symbols or know blocks), so that it is possible to perform a jointing control of the first layer information and second layer information and reduce the probability of failure of erasure correction due to minimum stopping sets.

The disclosures of Japanese Patent Application No. 2007-036941, filed on Feb. 16, 2007, and Japanese Patent Application No. 2008-033241, filed on Feb. 14, 2008, including the specifications, drawings and abstracts, are incorporated herein by reference in their entirety.

### INDUSTRIAL APPLICABILITY

The present invention provides an advantage of improving the error rate characteristics of the second information sequence when transmitting the first information sequence and second information sequence, and is applicable to a wide range of the communication system formed with, for example, base stations and mobile terminals.

1-24. (canceled)

25. A transmitting apparatus that transmits a first information sequence which secures received quality at ease and a second information sequence which hardly secures received quality, the transmitting apparatus comprising:
a first encoder that encodes the first information sequence;
a second encoder that encodes a sequence jointing the first information sequence and the second information sequence; and
a transmitting section that transmits encoded sequences acquired in the first and second encoders.

26. The transmitting apparatus according to claim 25, wherein the transmitting section transmits:
the encoded sequence of the first information sequence acquired in the first encoder, and
the encoded sequence of the second information sequence formed with the second information sequence and a parity sequence, except for the first information sequence from the first information sequence, the second information sequence and the parity sequence acquired in the second encoder.

27. The transmitting apparatus according to claim 25, wherein the second information sequence is transmitted by a transmitting method that makes error rate characteristics of the second information sequence poorer than the first information sequence on a receiving side, or in an environment where the second information sequence is susceptible to an influence of noise or interference.

28. The transmitting apparatus according to claim 25, wherein the first information sequence needs to be received in a state where error rate characteristics of the first information is better than the second information sequence.

29. The transmitting apparatus according to claim 25, wherein the first and second encoders are one of block encoders, organized block encoders and low density parity check encoders.

30. The transmitting apparatus according to claim 25, wherein:
the first information sequence is transmitted in a primary broadcast channel; and
the second information sequence is transmitted in a non-primary broadcast channel.

31. The transmitting apparatus according to claim 25, wherein:
the first and second information sequences comprise data of varying layers in digital broadcasting; and
the second information sequence comprises data of a lower layer than the first information sequence.

32. The transmitting apparatus according to claim 25, wherein:
the first and second information sequences comprise retransmission data; and
the transmitting section transmits only a parity sequence from the encoded sequence acquired in the second encoder.

33. The transmitting apparatus according to claim 25, wherein:
the first and second encoders generate first and second parity sequences using a low density parity check matrix H; and
the parity check matrix H is formed with:
a submatrix H1 for finding the first parity sequence from the first information sequence; and
a submatrix H2 for finding the second parity sequence from the first information sequence and the second information sequence.

34. The transmitting apparatus according to claim 33, wherein:
the first encoder generates the first parity sequence from the first information sequence using the submatrix H1; and
the second encoder generates the second parity sequence from the first information sequence and the second information sequence using the submatrix H2.

35. The transmitting apparatus according to claim 33, wherein the first encoder comprises a known bit inserting section that inserts a bit in a predetermined position in the first information sequence.

36. The transmitting apparatus according to claim 35, wherein the known bit inserting section inserts the bit in a column that comprises more 1's included in rows of a submatrix H2 for finding the second parity sequence, among columns corresponding to the first information sequence of the parity check matrix H.

37. The transmitting apparatus according to claim 35, wherein the known bit inserting section inserts the bit sequentially in a column that comprises more 1's included in a row of a submatrix H2 for finding the second parity sequence, among columns corresponding to the first information sequence of the parity check matrix H.

38. The transmitting apparatus according to claim 35, further comprising a known bit count determining section that determines a number of bits to insert in the first information sequence, based on received quality that is fed back from a communicating party.

39. The transmitting apparatus according to claim 33, wherein:
the first information sequence is arranged in a first information block;
the second information sequence is arranged in a second information block; and
the first and second encoders generate the first and second parity sequences in first information block units and in second information block units.

40. The transmitting apparatus according to claim 39, further comprising a known block inserting section that inserts a block in a predetermined position of the first information block.

41. The transmitting apparatus according to claim 40, wherein the known block inserting section inserts a block in a position corresponding to a column forming a minimum stopping set in a parity check matrix H.

42. A receiving apparatus comprising:
a first decoder that decodes a first encoded sequence to acquire a first information sequence; and
a second decoder that decodes data jointing the first information sequence acquired in the first decoder and a second encoded sequence to acquire a second information sequence.

43. The receiving apparatus according to claim 42, wherein:
the first and second encoded sequences comprise data subjected to low density parity check coding; and
the second decoder comprises:
a matrix multiplying section that multiplies a submatrix that is related to the first information sequence in a parity check matrix of low density parity check code, and the first information sequence; and
a low density parity check decoder that performs low density parity check decoding using a submatrix that is related to the second information sequence and a parity sequence, in the parity check matrix, and a multiplication result in the matrix multiplying section.

44. The receiving apparatus according to claim 43, wherein the low density parity check decoder involves multiplication of positive and negative signs of the multiplication result, in a row processing calculation equation of low density parity check decoding.
